(19) United States
(12) Patent Application Publication
(10) Pub. No.: US 2011/0235407 A1
(43) Pub. Date: Sep. 29, 2011

(54) SEMICONDUCTOR MEMORY DEVICE AND A METHOD OF MANUFACTURING THE SAME

(76) Inventors: Sun-me Lim, Hwaseong-si (KR); Han-byung Park, Seongnam-si (KR); Yong-shik Kim, Seoul (KR); Hee-bum Hong, Seoul (KR)

(21) Appl. No.: 13/043,009

(22) Filed: Mar. 8, 2011

(30) Foreign Application Priority Data
Mar. 24, 2010 (KR) 10-2010-0026406
Jan. 5, 2011 (KR) 10-2011-0001087

(51) Int. Cl. G11C 11/407; G11C 11/00; H01L 23/52

(52) U.S. Cl. 365/156; 365/154; 257/211; 257/E23.141

(57) ABSTRACT

A semiconductor memory device including a substrate, wherein the substrate includes first, second and third well regions, the first well region is disposed between the second and third well regions, the first well region includes a first type conductor and the second and third well regions each include a second type conductor. The semiconductor memory device includes first and second pull-up devices disposed in a line in the first well region and sharing a power supply voltage terminal, a first pull-down device disposed in the second well region, wherein the first pull-down device is adjacent to the first pull-up device, a second pull-down device disposed in the third well region, wherein the second pull-down device is adjacent to the second pull-up device, a first access device disposed in the second well region, wherein the first access device is adjacent to the second pull-up device, and a second access device disposed in the third well region, wherein the second access device is adjacent to the first pull-up device.

### CROSS-REFERENCE TO RELATED APPLICATIONS

This application claims priority under 35 U.S.C. §119 to Korean Patent Application No. 10-2010-0026406, filed on Mar. 24, 2010 and Korean Patent Application No. 10-2011-0001087, filed on Jan. 5, 2011, in the Korean Intellectual Property Office, the disclosures of which are incorporated by reference herein in their entireties.

### BACKGROUND

1. Technical Field

The inventive concept relates to semiconductor devices, and more particularly, to a semiconductor memory device and a method of manufacturing the same.

2. Discussion of the Related Art

Semiconductor memory devices may be classified as those having volatile memory and non-volatile memory. Dynamic random access memory (DRAM) and static random access memory (SRAM) are examples of semiconductor devices with volatile memory. Flash memory is an example of a semiconductor device with non-volatile memory.

In particular, SRAM is faster and less power hungry than DRAM. SRAM is also easier to control than DRAM. Further, unlike DRAM, SRAM does not require information stored therein to be periodically refreshed. Thus, SRAM can be easy to design with, since it does not require the additional circuitry and timing needed to introduce the refresh.

### SUMMARY

According to an exemplary embodiment of the inventive concept, there is provided a semiconductor memory device that includes a substrate, wherein the substrate includes first, second and third well regions, the first well region is disposed between the second and third well regions, the first well region includes a first type conductor and the second and third well regions each include a second type conductor, the semiconductor memory device further includes first and second pull-up devices disposed in a line in the first well region and sharing a power supply voltage terminal; a first pull-down device disposed in the second well region, wherein the first pull-down device is adjacent to the first pull-up device; a second pull-down device disposed in the third well region, wherein the second pull-down device is adjacent to the second pull-up device; a first access device disposed in the second well region, wherein the first access device is adjacent to the second pull-up device; and a second access device disposed in the third well region, wherein the second access device is adjacent to the first pull-up device.

The first and second pull-up devices may be disposed in one active region, wherein the active region is included in the first well region.

The first pull-up device and the first pull-down device may form a first inverter, and the second pull-up device and the second pull-down device may form a second inverter. The first access device may be connected to input terminals of the second inverter and output terminals of the first inverter, and the second access device may be connected to input terminals of the first inverter and output terminals of the second inverter.

The first access device may include a first access transistor that is controlled according to a voltage applied to a word line and connects a first bit line among a pair of bit lines to input terminals of the second inverter and output terminals of the first inverter. The second access device may include a second access transistor that is controlled according to the voltage applied to the word line and connects a second bit line among the pair of bit lines to input terminals of the first inverter and output terminals of the second inverter.

The first access device and the first pull-down device may be disposed in a line in one active region, wherein the active region is included in the second well region. The second access device and the second pull-down device may be disposed in a line in one active region, wherein the active region is included in the third well region.

The first type conductor may be an N type conductor, and the second type conductor may be a P type conductor. The first pull-up device may include a P-channel transistor having a source connected to the power supply voltage terminal. The first pull-down device may include an N-channel transistor having a drain connected to a drain of the P-channel transistor, a gate connected to a gate of the P-channel transistor, and a source connected to a ground voltage terminal. The second pull-up device may include a P-channel transistor having a source connected to the power supply voltage terminal. The second pull-down device may include an N-channel transistor having a drain connected to a drain of the P-channel transistor, a gate connected to a gate of the P-channel transistor, and a source connected to a ground voltage terminal. The first access device may include an N-channel transistor having a gate connected to a word line, and the second access device may include an N-channel transistor having a gate connected to the word line.

The semiconductor memory device may be included in an electronic system, the electronic system including a memory unit, a processor and an input/output device that communicate with each other via a bus, wherein the processor includes a storage device that includes the semiconductor memory device.

According to an exemplary embodiment of the inventive concept, there is provided a semiconductor memory device including a substrate, wherein the substrate includes first, second and third well regions, the first well region is disposed between the second and third well regions, the first well region includes a first type conductor and the second and third well regions each include a second type conductor; a first active region that is included in the first well region, wherein first and second pull-up devices are disposed in a line in the first active region; a second active region that is included in the second well region, wherein a first access device and a first pull-down device are disposed in the second active region, the first access device is disposed adjacent to the second pull-up device and the first pull-down device is disposed adjacent to the first pull-up device; and a third active region that is included in the third well region, wherein a second access device and a second pull-up device are disposed in the third active region, the second access device is disposed adjacent to the first pull-up device and the second pull-down device is disposed adjacent to the second pull-up device.

The first and second pull-up devices may be disposed in a line in a first direction. The first pull-up device may be disposed adjacent to the first pull-down device and the second access device in a second direction perpendicular to the first direction, and the second pull-up device may be disposed adjacent to the second pull-down device and the first access device in the second direction.

The semiconductor memory device may further include a first gate electrode disposed on the substrate to cross lower parts of the first and second active regions; and a second gate electrode disposed on the substrate to cross upper parts of the first and third active regions. The first pull-up device and the first pull-down device may be commonly connected to the first gate electrode to form a first inverter, and the second pull-up device and the second pull-down device may be commonly connected to the second gate electrode to form a second inverter.

The semiconductor memory device may further include a first metallic interconnection layer for connecting the first access device to input terminals of the second inverter and output terminals of the first inverter; and a second metallic interconnection layer for connecting the second access device to input terminals of the first inverter and output terminals of the second inverter. The first and second metallic interconnection layers may be disposed on the same layer. The first and second metallic interconnection layers may be disposed on different layers.

The semiconductor memory device may further include a third gate electrode disposed on the substrate to cross an upper part of the second active region; and a fourth gate electrode disposed on the substrate to cross a lower part of the third active region. The semiconductor memory device may further include a word line disposed on the substrate to extend in a direction parallel with the third and fourth gate electrodes to be connected to the third and fourth gate electrodes.

The semiconductor memory device may further include a pair of bit lines disposed on the substrate to extend in a direction parallel with the first to third active regions. A first bit line from among the pair of bit lines may be connected to the first access device, and a second bit line from among the pair of bit lines may be connected to the second access device.

The semiconductor memory device may further include a power supply voltage line disposed on the substrate in a direction parallel with the first to third active regions. The power supply voltage line may be connected to the first and second pull-up devices via a contact plug disposed between the first and second pull-up devices.

The first type conductor may be an N type conductor, and the second type conductor may be a P type conductor. The first and second pull-up devices may be P-channel transistors, and the first and second pull-down devices and the first and second access devices may be N-channel transistors.

According to an exemplary embodiment of the inventive concept, there is provided a method of manufacturing a semiconductor memory device, the method including receiving a substrate, wherein the substrate includes first, second and third well regions, wherein the first well region is disposed between the second and third well regions, the first well region includes a first type conductor and the second and third well regions each include a second type conductor; forming first and second pull-up devices in a line in a first active region, wherein the first active region is included in the first well region; forming a first pull-down device and a first access device in a second active region, wherein the second active region is included in the second well region, the first pull-down device is adjacent to the first pull-up device and the first access device is adjacent to the second pull-up device; and forming a second pull-down device and a second access device in a third active region, wherein the third active region is included in the third well region, the second pull-down device is adjacent to the second pull-up device and the second access device is adjacent to the first pull-up device.

The first and second pull-up devices may be disposed in a line in a first direction. The first pull-up device may be disposed adjacent to the first pull-down device and the second access device in a second direction perpendicular to the first direction. The second pull-up device may be disposed adjacent to the second pull-down device and the first access device in the second direction.

The method may further include forming a plurality of conductive patterns on the substrate to cross over part of at least one of the first to third active regions, and wherein the first pull-up device and the first pull-down device may be commonly connected to one of the plurality of conductive patterns to form a first inverter, and the second pull-up device and the second pull-down device may be commonly connected to another conductive pattern of the plurality of conductive patterns to form a second inverter.

The method may further include forming a first metallic interconnection layer for connecting the first access device to input terminals of the second inverter and output terminals of the first inverter; and forming a second metallic interconnection layer for connecting the second access device to input terminals of the first inverter and output terminals of the second inverter.

The forming of the first and second metallic interconnection layers may include: forming a first insulating layer on the substrate; forming a plurality of first contact holes by etching parts of the first insulating layer, and forming a plurality of contact plugs by filling the plurality of first contact holes with a metal; forming a second insulating layer on the first insulating layer having the plurality of contact plugs; and forming a plurality of second contact holes by etching parts of the second insulating layer, and forming the first and second metallic interconnection layers by filling the plurality of second contact holes with a metal, wherein the first and second metallic interconnection layers may be connected to at least one of the first to third well regions via the plurality of contact plugs.

The method may further include forming a silicide layer in at least one of the first to third well regions, and wherein the plurality of contact plugs may be connected to the silicide layer.

According to an exemplary embodiment of the inventive concept, there is provided a semiconductor memory device that includes a substrate, wherein the substrate includes first, second and third well regions, the first well region is disposed between the second and third well regions, the first well region includes a first type conductor and the second and third well regions each include a second type conductor, the semiconductor memory device further includes first and second pull-down devices disposed in a line in the first well region and sharing a ground voltage terminal; a first pull-up device disposed in the second well region, wherein the first pull-up device is adjacent to the first pull-down device; a second pull-up device disposed in the third well region, wherein the second pull-up device is adjacent to the second pull-down device; a first access device disposed in the second well region, wherein the first access device is adjacent to the second pull-down device; and a second access device disposed in the third well region, wherein the second access device is adjacent to the first pull-down device.

The first and second pull-down devices may be disposed in one active region, wherein the active region is included in the first well region.

The first pull-down device and the first pull-up device may form a first inverter, and the second pull-down device and the second pull-up device may form a second inverter. The first access device may be connected to input terminals of the second inverter and output terminals of the first inverter. The second access device may be connected to input terminals of the first inverter and output terminals of the second inverter.

The first access device may include a first access transistor that is controlled according to a voltage applied to a word line and connects a first bit line among a pair of bit lines to input terminals of the second inverter and output terminals of the first inverter. The second access device may include a second access transistor that is controlled according to the voltage applied to the word line and connects a second bit line among the pair of bit lines to input terminals of the first inverter and output terminals of the second inverter.

The first access device and the first pull-up device may be disposed in a line in one active region, wherein the active region is included in the second well region. The second access device and the second pull-up device may be disposed in a line in one active region, wherein the active region is included in the third well region.

The first type conductor may be a P type conductor, and the second type conductor may be an N type conductor. The first pull-down device may include an N-channel transistor having a source connected to the ground voltage terminal, and the first pull-up device may include a P-channel transistor having a drain connected to a drain of the N-channel transistor, a gate connected to a gate of the N-channel transistor, and a source connected to a power supply voltage terminal. The second pull-down device may include an N-channel transistor having a source connected to the ground voltage terminal, and the second pull-up device may include a P-channel transistor having a drain connected to a drain of the N-channel transistor, a gate connected to a gate of the N-channel transistor, and a source connected to a power supply voltage terminal. The first access device may include a P-channel transistor having a gate connected to a word line, and the second access device may include a P-channel transistor having a gate connected to the word line.

The semiconductor memory device may be included in an electronic system, the electronic system including a memory unit, a processor and an input/output device that communicate with each other via a bus, wherein the processor includes a storage device that includes the semiconductor memory device.

According to an exemplary embodiment of the inventive concept, there is provided a semiconductor memory device that includes a substrate, wherein the substrate includes first, second and third well regions, wherein the first well region is disposed between the second and third well regions, the first well region includes a first type conductor and the second and third well regions each include a second type conductor; a first active region that is included in the first well region, wherein first and second pull-down devices are disposed in a line in the first active region; a second active region that is included in the second well region, wherein a first access device and a first pull-up device are included in the second active region, the first access device is disposed adjacent to the second pull-down device and the first pull-up device is disposed adjacent to the first pull-down device; and a third active region that is included in the third well region, wherein a second access device and a second pull-up device are included in the third active region, the second access device is disposed adjacent to the first pull-down device and the second pull-up device is disposed adjacent to the second pull-down device.

The first and second pull-down devices may be disposed in a line in a first direction. The first pull-down device may be disposed adjacent to the first pull-up device and the second access device in a second direction perpendicular to the first direction. The second pull-down device may be disposed adjacent to the second pull-up device and the first access device in the second direction.

The semiconductor memory device may further include a first gate electrode disposed on the substrate to cross lower parts of the first and second active regions; and a second gate electrode disposed on the substrate to cross upper parts of the first and third active regions. The first pull-down device and the first pull-up device are commonly connected to the first gate electrode to form a first inverter, and the second pull-down device and the second pull-up device are commonly connected to the second gate electrode to form a second inverter.

The semiconductor memory device may further include a first metallic interconnection layer for connecting the first access device to input terminals of the second inverter and output terminals of the first inverter; and a second metallic interconnection layer for connecting the second access device to input terminals of the first inverter and output terminals of the second inverter. The first and second metallic interconnection layers may be disposed on the same layer. The first and second metallic interconnection layers may be disposed on different layers.

The semiconductor memory device may further include a third gate electrode disposed on the substrate to cross an upper part of the second active region; and a fourth gate electrode disposed on the substrate to cross a lower part of the third active region. The semiconductor memory device may further include a word line disposed on the substrate to extend in a direction parallel with the third and fourth gate electrodes to be connected to the third and fourth gate electrodes.

The semiconductor memory device may further include a pair of bit lines disposed on the substrate to extend in a direction parallel with the first to third active regions. A first bit line from among the pair of bit lines may be connected to the first access device, and a second bit line from among the pair of bit lines may be connected to the second access device.

The semiconductor memory device may further include a ground voltage line disposed on the substrate in a direction parallel with the first to third active regions. The ground voltage line may be connected to the first and second pull-down devices via a contact plug disposed between the first and second pull-down devices.

The first type conductor may be a P type conductor, and the second type conductor may be an N type conductor. The first and second pull-down devices may be N-channel transistors, and the first and second pull-up devices and the first and second access devices may be P-channel transistors.

According to an exemplary embodiment of the inventive concept, there is provided a method of manufacturing a semiconductor memory device, the method including receiving a substrate, wherein the substrate includes first, second and third well regions, the first well region is disposed between the second and third well regions, the first well region includes a first type conductor and the second and third well regions each include a second type conductor; forming first and second pull-down devices in a line in a first active region, wherein the first active region is included in the first well region; forming a first pull-up device and a first access device in a second active region, wherein the second active region is included in the second well region, the first pull-up device is adjacent to the first pull-down device and the first access device is adjacent to the second pull-down device; and forming a second pull-up device and a second access device in a third active region, wherein the third active region is included in the third well region, the second pull-up device is adjacent to the second pull-down device and the second access device to be adjacent to the first pull-down device.

The first and second pull-down devices may be disposed in a line in a first direction. The first pull-down device may be disposed adjacent to the first pull-up device and the second access device in a second direction perpendicular to the first direction. The second pull-down device may be disposed adjacent to the second pull-up device and the first access device in the second direction.

The method may further include forming a plurality of conductive patterns on the substrate to cross over part of at least one of the first to third active regions, and wherein the first pull-down device and the first pull-up device may be commonly connected to one of the plurality of conductive patterns to form a first inverter, and the second pull-down device and the second pull-up device may be commonly connected to another conductive pattern of the plurality of conductive patterns to form a second inverter.

The method may further include forming a first metallic interconnection layer for connecting the first access device to input terminals of the second inverter and output terminals of the first inverter; and forming a second metallic interconnection layer for connecting the second access device to input terminals of the first inverter and output terminals of the second inverter.

According to an exemplary embodiment of the inventive concept, there is provided a semiconductor memory device that includes a substrate, the substrate including first, second and third well regions, wherein the first well region is disposed between the second and third well regions, the first well region includes a first type conductor, and the second and third well regions each include a second type conductor, and wherein the first well region includes a first stacked structure, the first stacked structure including a first contact plug, a first metallic insulating layer, a via plug and a power supply or ground voltage line sequentially stacked on a first single active layer; the second well region includes a second stacked structure, the second stacked structure including a second contact plug and a second metallic insulating layer sequentially stacked on a second single active layer; and the third well region includes a third stacked structure, the third stacked structure including a third contact plug and a third metallic insulating layer sequentially stacked on a third single active layer.

### BRIEF DESCRIPTION OF THE DRAWINGS

The above and other features of the inventive concept will become more apparent by describing in detail exemplary embodiments thereof with reference to the accompanying drawings in which:

FIG. 1 is a layout diagram of a semiconductor memory device according to an exemplary embodiment of the inventive concept;

FIG. 2 is a layout diagram schematically illustrating metallic interconnection layers of the semiconductor memory device of FIG. 1, according to an exemplary embodiment of the inventive concept;

FIG. 3 is a layout diagram schematically illustrating bit line interconnection layers of the semiconductor memory device of FIG. 1, according to an exemplary embodiment of the inventive concept;

FIG. 4 is a layout diagram schematically illustrating word line interconnection layers of the semiconductor memory device of FIG. 1, according to an exemplary embodiment of the inventive concept;

FIG. 5 is a circuit diagram of an equivalent circuit of the semiconductor memory device of FIG. 1, according to an exemplary embodiment of the inventive concept;

FIG. 6 is a cross-sectional view of the semiconductor memory device of FIG. 1, taken along line

FIG. 7 is a cross-sectional view of the semiconductor memory device of FIG. 1, taken along line II-II′;

FIGS. 8A to 8G are cross-sectional views illustrating a method of manufacturing a semiconductor memory device, according to an exemplary embodiment of the inventive concept;

FIG. 9 is a layout diagram of a semiconductor memory device according to an exemplary embodiment of the inventive concept;

FIG. 10 is a circuit diagram of an equivalent circuit of the semiconductor memory device of FIG. 9, according to an exemplary embodiment of the inventive concept;

FIG. 11 is a layout diagram of a semiconductor memory device according to an exemplary embodiment of the inventive concept;

FIG. 12 is a layout diagram schematically illustrating metallic interconnection layers of the semiconductor memory device of FIG. 11, according to an exemplary embodiment of the inventive concept;

FIG. 13 is a layout diagram schematically illustrating bit line interconnection layers of the semiconductor memory device of FIG. 11, according to an exemplary embodiment of the inventive concept;

FIG. 14 is a layout diagram schematically illustrating word line interconnection layers of the semiconductor memory device of FIG. 11, according to an exemplary embodiment of the inventive concept;

FIG. 15 is a circuit diagram of an equivalent circuit of the semiconductor memory device of FIG. 11, according to an exemplary embodiment of the inventive concept;

FIG. 16 is a cross-sectional view of the semiconductor memory device of FIG. 11, taken along line III-III′;

FIG. 17 is a cross-sectional view of the semiconductor memory device of FIG. 11, taken along line IV-IV′;

FIGS. 18A to 18G are cross-sectional views illustrating a method of manufacturing a semiconductor memory device, according to an exemplary embodiment of the inventive concept;

FIG. 19 is a layout diagram of a semiconductor memory device according to an exemplary embodiment of the inventive concept;

FIG. 20 is a circuit diagram of an equivalent circuit of the semiconductor memory device of FIG. 11, according to an exemplary embodiment of the inventive concept;

FIG. 21 is a flowchart illustrating a method of manufacturing a semiconductor memory device, according to an exemplary embodiment of the inventive concept;

FIG. 22 is a flowchart illustrating a method of manufacturing a semiconductor memory device, according to an exemplary embodiment of the inventive concept; and

FIG. 23 is a schematic block diagram of an electronic system according to an exemplary embodiment of the inventive concept.

### DETAILED DESCRIPTION OF THE EMBODIMENTS

Exemplary embodiments of the inventive concept will be described more fully hereinafter with reference to the accompanying drawings. The inventive concept may, however, be embodied in many different forms and should not be construed as limited to the exemplary embodiments set forth herein.

It will be understood that when an element or layer is referred to as being “on,” “connected to” or “coupled to” another element or layer, the element or layer may be directly on, connected to or coupled to the another element or layer or intervening elements or layers may be present. In the drawings, the lengths and sizes of layers and regions may be exaggerated for clarity. Like numbers may refer to like elements throughout the specification and drawings.

The following exemplary embodiments of the inventive concept will now be described, for example, with respect to a static random access memory (SRAM) which is a type of semiconductor memory device. However, an exemplary embodiment of the inventive concept is not limited to an SRAM and may be applied, for example, to semiconductor memory devices having two inverters.

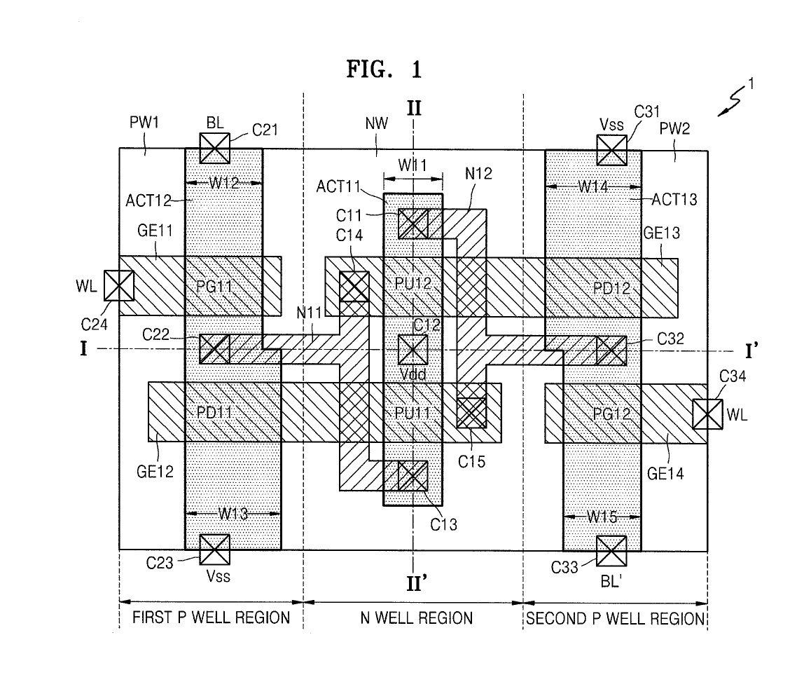

FIG. 1 is a layout diagram of a semiconductor memory device 1 according to an exemplary embodiment of the inventive concept. Referring to FIG. 1, the semiconductor memory device 1 may include a static random access memory (SRAM) cell formed on a substrate, in which a first well region NW, and a second well region PW1 and a third well region PW2 having the first well region NW therebetween are defined. The first well region NW may be a first conductive type and the second and third well regions PW1 and PW2 may be a second conductive type. In the current embodiment, the first conductive type may be an N type and the second conductive type may be a P type. Hereinafter, it is assumed that the first well region NW is an N well region NW, the second well region PW1 is a first P well region PW1, and the third well region PW2 is a second P well region PW2.

The N well region NW is a region in which an N type well is formed, for example, through ion implantation. The N well region NW includes a first active region ACT11 defined by an isolation layer. In the current embodiment, the first active region ACT11 may be one bar-type active region formed to be long in the vertical direction. A P type diffusion region may be formed by doping P+ type impurities onto the first active region ACT11. In addition, first to third contact plugs C11, C12, and C13 may be formed in the first active layer region ACT11. In the first active region ACT11, two pull-up devices may be formed in a line. In the current embodiment, the two pull-up devices may be first and second PMOS transistors PU1 and PU2.

As described above, the two pull-up devices, e.g., the first and second PMOS transistors PU11 and PU12, may be disposed in the first active region ACT11 which is one active region, thereby minimizing a mismatch between the first and second PMOS transistors PU11 and PU12. In particular, a dispersion between a threshold voltage of the first PMOS transistor PU11 and a threshold voltage of the second PMOS transistor PU12 may be reduced.

The first P well region PW1 is a region in which a P type well is formed, for example, through ion implantation. The first P well region PW1 includes a second active region ACT12 defined by an isolation layer. In the current embodiment, the second active region ACT12 may be one active region that extends in parallel with the first active region ACT11. An N type diffusion region may be formed by doping N+ type impurities onto the second active region ACT12. In addition, fourth to sixth contact plugs C21, C22, and C23 may be formed in the second active region ACT12. In the second active region ACT12, one pull-down device and one access device may be formed. In the current embodiment, the pull-down device may be a first NMOS transistor PD11 and the access device may be a third NMOS transistor PG11.

The second P well region PW2 is a region in which a P type well is formed, for example, through ion implantation. The second P well region PW2 includes a third active region ACT13 defined by an isolation layer. In the current embodiment, the third active region ACT13 may one active region that extends in parallel with the first active region ACT11. An N type diffusion region may be formed by doping N+ type impurities onto the third active region ACT13. In addition, seventh to ninth contact plugs C31, C32, and C33 may be formed in the third active region ACT13. In the third active region ACT13, one pull-down device and one access device may be formed. In the current embodiment, the pull-down device may be a second NMOS transistor PD12 and the access device may be a fourth NMOS transistor PG12.

The widths of the first to third active regions ACT11, ACT12, and ACT13 will now be compared with one another. The first active region ACT11 may have a uniform width, i.e., a first width W11. A width of the second active region ACT12 may not be uniform. Particularly, a third width W13 of a part of the second active region ACT12 in which the first NMOS transistor PD11 is disposed, may be greater than a second width W12 of the other part of the second active region ACT12 in which the third NMOS transistor PG11 is disposed, and the second and third widths W12 and W13 may be greater than the first width W11. A width of the third active region ACT13 may not also be uniform. Particularly, a fourth width W14 of the third active region ACT13 in which the second NMOS transistor PD12 is disposed, may be greater than a fifth width W15 of the other part of the third active region ACT13 in which the fourth NMOS transistor PG12 is disposed, and the fourth and fifth widths W14 and W15 may be greater than the first width W11. In addition, the fourth width W14 may be substantially the same as the third width W13, and the fifth width W15 may be substantially the same as the second width W12.

If the third and fourth widths W13 and W14 of the second and third active regions ACT12 and ACT13 in which the first and second NMOS transistors PD11 and PD12 are formed, respectively, are greater than the other widths W11, W12, and W15 as described above, then the speed of performing a pull-down operation with the first and second NMOS transistors PD11 and PD12 may increase. In addition, if the second and fifth widths W12 and W15 of the second and third active regions ACT12 and ACT13 in which the third and fourth NMOS transistors PG11 and PG12 are formed, respectively, are greater than the first width W11 of the first active region ACT11 in which the first and second PMOS transistors PU11 and PU12 are formed as described above, then the speed of performing a write operation on the semiconductor memory device 1 may increase.

First to fourth gate electrodes GE11, GE12, GE13, and GE14 are formed on the substrate in which the first to third active regions ACT11, ACT12, and ACT13 are defined. Specifically, the first gate electrode GE11 is disposed to cross the second active region ACT12, the second gate electrode GE12 is disposed to cross the first and second active regions ACT11 and ACT12, the third gate electrode GE13 is disposed to cross the first and third active regions ACT11 and ACT13, and the fourth gate electrode GE14 is disposed to cross the third active region ACT13. Word line contact plugs C24 and C34 are formed on the first and fourth gate electrodes GE11 and GE14, respectively. Interconnection contact plugs C15 and C14 are formed on the second and third gate electrode GE12 and GE13, respectively. For example, the first to fourth gate electrodes GE11 to GE14 may be poly-silicon layers.

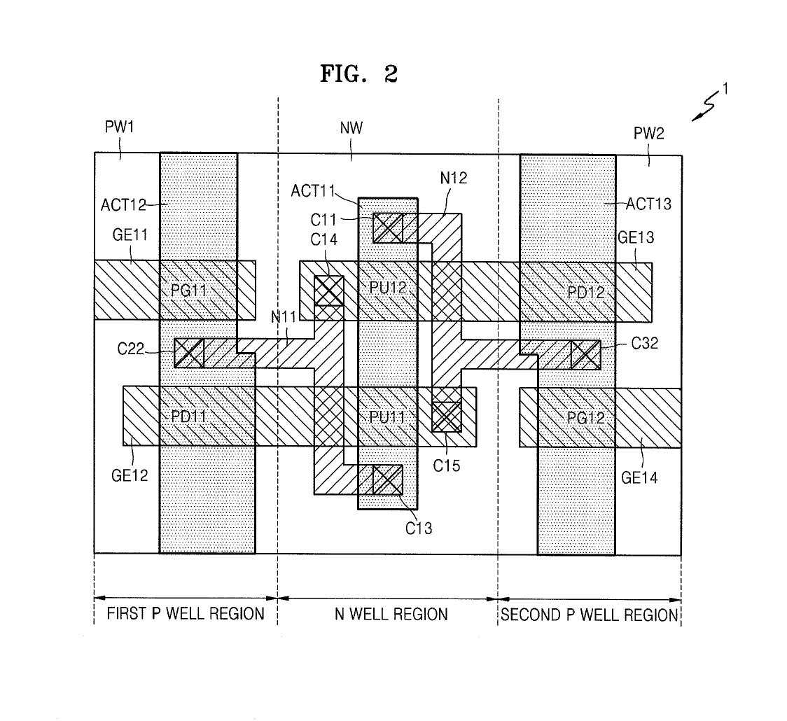

FIG. 2 is a layout diagram schematically illustrating first and second metallic interconnection layers N11 and N12 of the semiconductor memory device 1 of FIG. 1, according to an exemplary embodiment of the inventive concept. Referring to FIG. 2, the first and second metallic interconnection layers N11 and N12 are formed on the substrate having the first to fourth gate electrodes GE11 to GE14. The first metallic interconnection layer N11 connects the third contact plug C13 formed on the first active region ACT11, the fifth contact plug C22 formed on the second active region ACT12, and the interconnection contact plug C14 formed on the third gate electrode GE13 to one another. The second metallic interconnection layer N12 connects the first contact plug C11 formed on the first active region ACT11, the eighth contact plug C32 formed on the third active region ACT13, and the interconnection contact plug C15 formed on the second gate electrode GE12 to one another. For example, the first and second metallic interconnection layers N11 and N12 may be formed of at least one metal selected from the group consisting of tungsten (W), aluminum (Al), copper (Cu), molybdenum (Mo), titanium (Ti), tantalum (Ta), and ruthenium (Ru), or an alloy thereof, or may be poly-silicon layers.

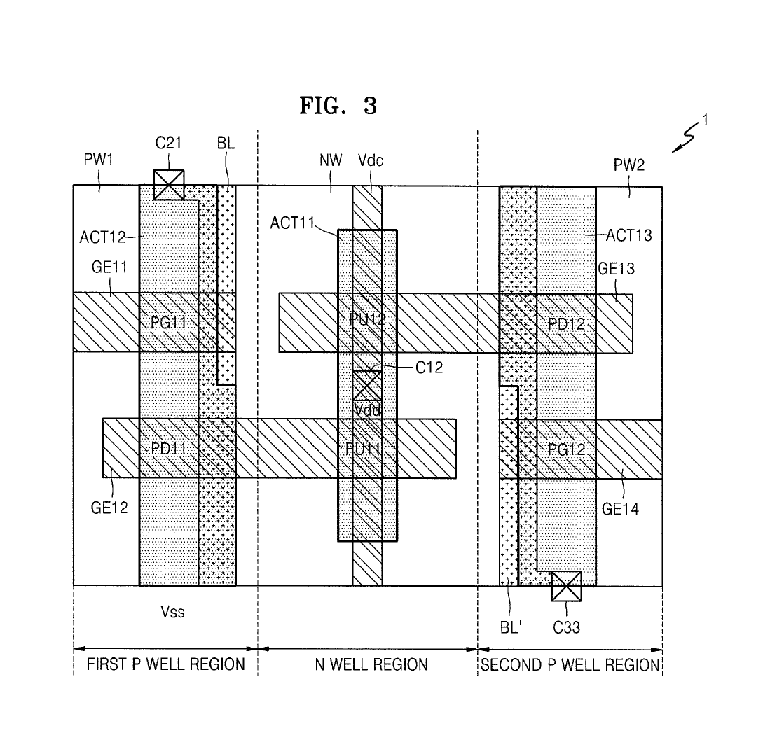

FIG. 3 is a layout diagram schematically illustrating bit line interconnection layers of the semiconductor memory device 1 of FIG. 1, according to an exemplary embodiment of the inventive concept. Referring to FIG. 3, a pair of a bit line BL and a complementary bit line BL′ are formed on the substrate having the first and second metallic interconnection layers N11 and N12. The bit line BL and the complementary bit line BL′ may extend to be parallel with the first to third active regions ACT11, ACT12, and ACT13. In this case, the bit line BL is connected to the second active region ACT12 via the fourth contact plug C21 formed in the second active region ACT12, and the complementary bit line BL′ is connected to the third active region ACT13 via the ninth contact plug C33 formed in the third active region ACT13.

In addition, a power supply voltage line Vdd is formed on the substrate having the first and second metallic interconnection layers N11 and N12. The power supply voltage line Vdd may be disposed between the pair of bit lines BL and BL′ and may extend in parallel with the pair of bit lines BL and BL′. The power supply voltage line Vdd is connected to the first active region ACT11 via the second contact plug C12 formed in the first active region ACT11.

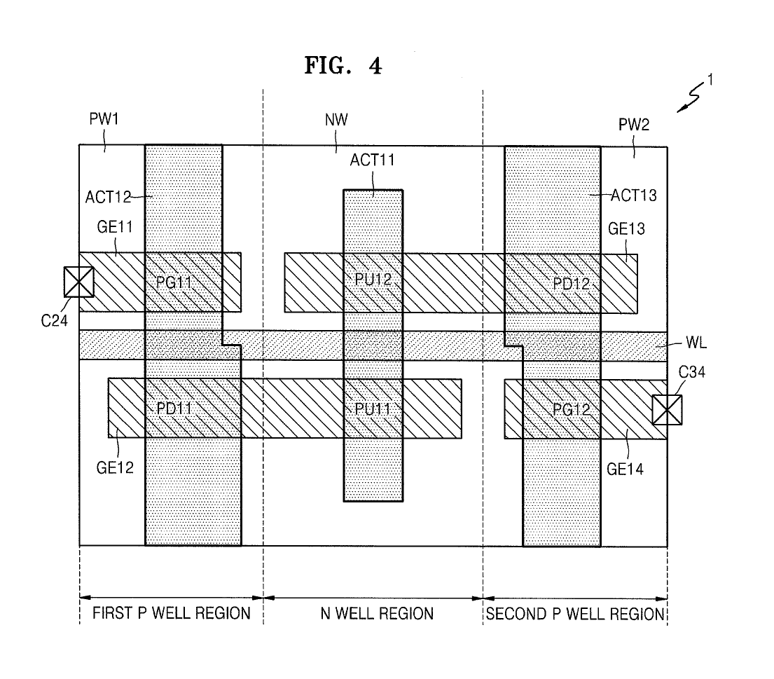

FIG. 4 is a layout diagram schematically illustrating word line interconnection layers of the semiconductor memory device 1 of FIG. 1, according to an exemplary embodiment of the inventive concept. Referring to FIG. 4, a word line WL is formed on the substrate having the pair of bit lines BL and BL′. The word line WL may extend in parallel with the first to fourth gate electrodes GE11, GE12, GE13, and GE14. The word line WL is connected to the first and fourth gate electrodes GE11 and GE14 via the word line contact plugs C24 and C34, respectively. Although not shown, a metallic interconnection layer may further be formed to connect the word line WL to the word line contact plugs C24 and C34.

In the current embodiment, the word line WL is disposed on the pair of bit lines BL and BL′, but an exemplary embodiment of the inventive concept is not limited thereto and the pair of bit lines BL and BL′ may be formed on the word line WL.

Referring back to FIG. 1, the first PMOS transistor PU11 is defined by the second gate electrode GE12 on the first active region ACT11 and the second and third contact plugs C12 and C13 having the second gate electrode GE12 therebetween in the first active region ACT11. Here, the second contact plug C12, the second gate electrode GE12, and the third contact plug C13 correspond to a source, gate, and drain of the first PMOS transistor PU11, respectively.

The first NMOS transistor PD11 is defined by the second gate electrode GE12 on the second active region ACT12 and the fifth and sixth contact plugs C22 and C23 having the second gate electrode GE12 therebetween in the second active region ACT12. Here, the fifth contact plug C22, the second gate electrode GE12, and the sixth contact plug C23 correspond to a drain, gate, and source of the first NMOS transistor PD11, respectively.

The second PMOS transistor PU12 is defined by the third gate electrode GE13 on the first active region ACT11 and the first and second contact plugs C11 and C12 having the third gate electrode GE13 therebetween in the first active region ACT11. Here, the first contact plug C11, the third gate electrode GE13, and the second contact plug C12 correspond to a drain, gate, and source of the second PMOS transistor PU12, respectively.

The second NMOS transistor PD12 is defined by the third gate electrode GE13 on the third active region ACT13 and the seventh and eighth contact plugs C31 and C32 having the third gate electrode GE13 therebetween in the third active region ACT13. Here, the seventh contact plug C31, the third gate electrode GE13, and the eighth contact plug C32 correspond to a source, gate, and drain of the second NMOS transistor PD12, respectively.

In this case, the first PMOS transistor PU11 and the first NMOS transistor PD11 are commonly connected to the second gate electrode GE12, and are connected via the first metallic interconnection layer N11, thereby forming a first inverter. The second PMOS transistor PU12 and the second NMOS transistor PD12 are commonly connected to the third gate electrode GE13, and are connected via the second metallic interconnection layer N12, thereby forming a second inverter. In the semiconductor memory device 1, the first and second inverters form a latch for storing data.

The third NMOS transistor PG11 is defined by the first gate electrode GE11 on the second active region ACT12 and the fourth and fifth contact plugs C21 and C22 having the first gate electrode GE11 therebetween in the second active region ACT12. Here, the fourth and fifth contact plugs C21 and C22 correspond to a drain and source of the third NMOS transistor PG11, respectively, and the first gate electrode GE11 corresponds to a gate of the third NMOS transistor PG11. In this case, the fourth contact plug C21 is connected to the bit line BL, and the word line contact plug C24 on the first gate electrode GE11 is connected to the word line WL. The third NMOS transistor PG11 may act as a first pass gate or a first transmission gate.

The fourth NMOS transistor PG12 is defined by the fourth gate electrode GE14 on the third active region ACT13 and the eighth and ninth contact plugs C32 and C33 having the fourth gate electrode GE14 therebetween in the third active region ACT13. Here, the eighth and ninth contact plugs C32 and C33 correspond to a drain and source of the fourth NMOS transistor PG12, respectively, and the fourth gate electrode GE14 corresponds to a gate of the fourth NMOS transistor PG12. The ninth contact plug C33 is connected to the complementary bit line BL′, and the word line contact plug C34 on the fourth gate electrode GE14 is connected to the word line WL. The fourth NMOS transistor PG12 may act as a second pass gate or a second transmission gate.

In the semiconductor memory device 1 according to the current embodiment, the first and second PMOS transistors PU11 and PU12 are disposed in a line in the first active region ACT11 which is one active region. Thus, a patterning process does not need to be performed to separately form two active regions for the first and second PMOS transistors PU11 and PU12, respectively. Instead, a patterning process may be performed to form only the first active region ACT11. Since only one active region, i.e., the first active region ACT11, is formed for the first and second PMOS transistors PU11 and PU12 rather than two active regions, there is no need to form an isolation layer between two active regions. Accordingly, the length of a unit cell of the semiconductor memory device 1 in the horizontal direction is less than when two active regions are formed, thereby improving the integration degree of the semiconductor memory device 1.

In addition, in the semiconductor memory device 1 according to the current embodiment, the first and second PMOS transistors PU11 and PU12 in the first active region ACT11 share the second contact plug C12 connected to the power supply voltage line Vdd. Thus, two contact plugs do not need to be formed to apply a power supply voltage Vdd to the first and second PMOS transistors PU11 and PU12, and therefore, the length of a unit cell of the semiconductor memory device 1 in the vertical direction is less than when two contact plugs are formed, thereby improving the integration degree of the semiconductor memory device 1.

Furthermore, in the semiconductor memory device 1 according to the current embodiment, the first to third active regions ACT11, ACT12, and ACT13 are disposed to be parallel with one another, the first NMOS transistor PD11 is disposed in a location corresponding to the first PMOS transistor PU11 and the third NMOS transistor PG11 is disposed in a location corresponding to the second PMOS transistor PU12 in the second active region ACT12, and the fourth NMOS transistor PG12 is disposed in a location corresponding to the first PMOS transistor PU11 and the second NMOS transistor PD12 is disposed in a location corresponding to the second PMOS transistor PU12 in the third active region ACT13. As described above, in a unit cell of the semiconductor memory device 1, other transistors are disposed to be symmetrical with respect to the first and second PMOS transistors PU11 and PU12, thereby improving the integration degree of the semiconductor memory device 1. In addition, if a plurality of unit cells is disposed in the semiconductor memory device 1, an additional region is not required to be included in a boundary region.

As described above, according to the current embodiment, in the semiconductor memory device 1, P channel transistors are formed and N channel transistors or other devices may be formed to be symmetrical with respect to the P channel transistors, in one active region. In the current embodiment, the semiconductor memory device 1 includes six transistors, but an exemplary embodiment of the inventive concept is not limited thereto and the semiconductor memory device 1 may include four transistors and two resistive devices. Further, the semiconductor memory device 1 may include more than six transistors or less than six transistors.

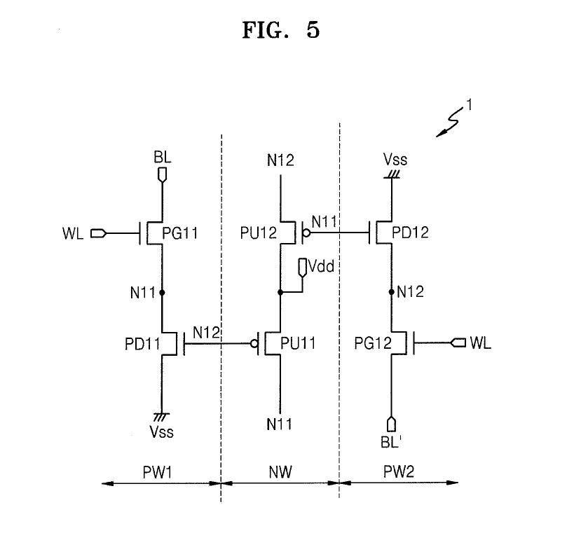

FIG. 5 is a circuit diagram of an equivalent circuit of the semiconductor memory device 1 of FIG. 1, according to an exemplary embodiment of the inventive concept. Referring to FIG. 5, the semiconductor memory device 1 includes the first and third NMOS transistors PD11 and PG11 disposed in the first P well region PW1, the first and second PMOS transistors PU11 and PU12 disposed in the N well region NW, and the second and fourth NMOS transistors PD12 and PG12 disposed in the second P well region PW2. In this case, the first PMOS transistor PU11 and the first NMOS transistor PD11 form a first inverter, and the second PMOS transistor PU12 and the second NMOS transistor PD12 form a second inverter.

The third NMOS transistor PG11 may be switched on or off according to a voltage applied to the word line WL and may connect the bit line BL to a first node N11. The first node N11 corresponds to the first metallic interconnection layer N11 of FIG. 1. In detail, if the voltage applied to the word line WL is logic ‘1’, then the third NMOS transistor PG11 may be turned on to connect the bit line BL to the first node N11. The first node N11 is connected to input terminals of the second inverter, e.g., the gates of the second PMOS transistor PU12 and the second NMOS transistor PD12, and is connected to output terminals of the first inverter, e.g., the drains of the first PMOS transistor PU11 and the first NMOS transistor PD11.

The fourth NMOS transistor PG12 may be switched on or off according to the voltage applied to the word line WL and may connect the complementary bit line BL′ to a second node N12. The second node N12 corresponds to the second metallic interconnection layer N12 of FIG. 1. In detail, if the voltage applied to the word line WL is logic ‘1’, then the fourth NMOS transistor PG12 may be turned on to connect the complementary bit line BL′ to the second node N12. The second node N12 is connected to input terminals of the first inverter, e.g., the gates of the first PMOS transistor PU11 and the first NMOS transistor PD11, and is connected to output terminals of the second inverter, e.g., the drains of the second PMOS transistor PU12 and the second NMOS transistor PD12.

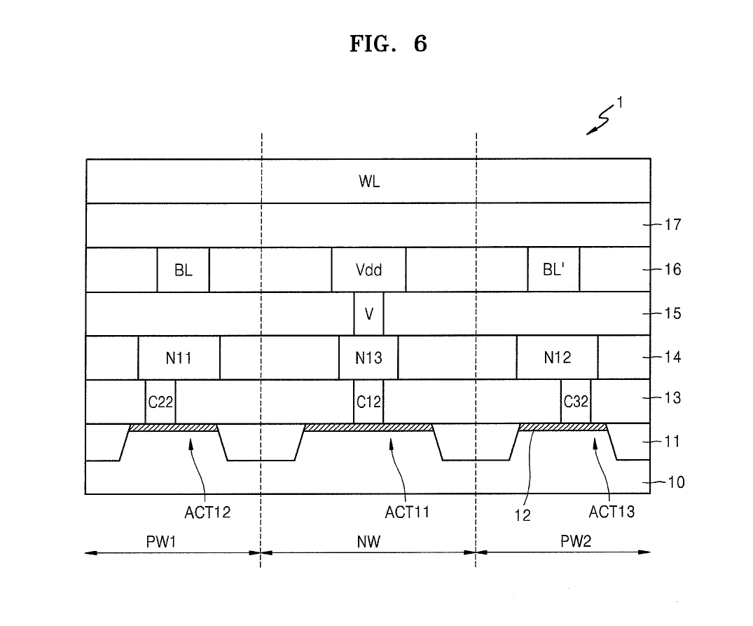

FIG. 6 is a cross-sectional view of the semiconductor memory device 1 of FIG. 1, taken along line I-I′. Referring to FIG. 6, the semiconductor memory device 1 is formed on a substrate 10 in which the N well region NW and the first and second P well regions PW1 and PW2 are defined. The substrate 10 may be a semiconductor substrate formed of, for example, silicon, a silicon-on-insulator, a silicon-on-sapphire, germanium, silicon-germanium, or gallium-arsenide. In the current embodiment, the substrate 10 may be a P type semiconductor substrate.

The N well region NW may be formed by implanting N type ions into the substrate 10, and the first and second P well regions PW1 and PW2 may be formed by implanting P type ions into the substrate 10. First to third active regions ACT11, ACT12, and ACT13 defined by an isolation layer 11 may be disposed in the N well region NW and the first and second P well regions PW1 and PW2, respectively. The isolation layer 11 may be a shallow trench isolation (STI) layer. A silicide layer 12 may be formed on the first to third active regions ACT11, ACT12, and ACT13.

A first insulating layer 13 is disposed on the substrate 10, and the fifth contact plug C22, the second contact plug C12, and the eighth contact plug C32 are disposed on the first insulating layer 13. The fifth contact plug C22 is connected to the second active region ACT12, the second contact plug C12 is connected to the first active region ACT11, and the eighth contact plug C32 is connected to the third active region ACT13. A second insulating layer 14 is disposed on the first insulating layer 13, and the first and second metallic interconnection layers N11 and N12 and a third metallic interconnection layer N13 are disposed on the second insulating layer 14. The third metallic interconnection layer N13 connects the power supply voltage line Vdd to the first active region ACT11.

A third insulating layer 15 is disposed on the second insulating layer 14, and a via plug V is disposed on the third insulating layer 15. A fourth insulating layer 16 is disposed on the third insulating layer 15, and the pair of bit lines BL and BL′ and the power supply voltage line Vdd are disposed on the fourth insulating layer 16. A fifth insulating layer 17 is disposed on the fourth insulating layer 16, and the word line WL is disposed on the fifth insulating layer 17.

The first to fifth insulating layers 13 to 17 may be formed of a silicon oxide film, phosphosilicate glass (PSG), borophosphosilicate glass (BPSG), or the like, or may be chemical vapor deposition (CVD) glass layers doped with a low dielectric material but an exemplary embodiment of the inventive concept is not limited thereto. The contact plugs C22, C12, and C32 and the via plug V may be formed of at least one metal selected from the group consisting of tungsten (W), aluminum (Al), copper (Cu), molybdenum (Mo), titanium (Ti), tantalum (Ta), and ruthenium (Ru) or an alloy thereof, but an exemplary embodiment of the inventive concept is not limited thereto and the contact plugs C22, C12, and C32 and the via plug V may be conductive nitrides of at least one metal selected from the above group.

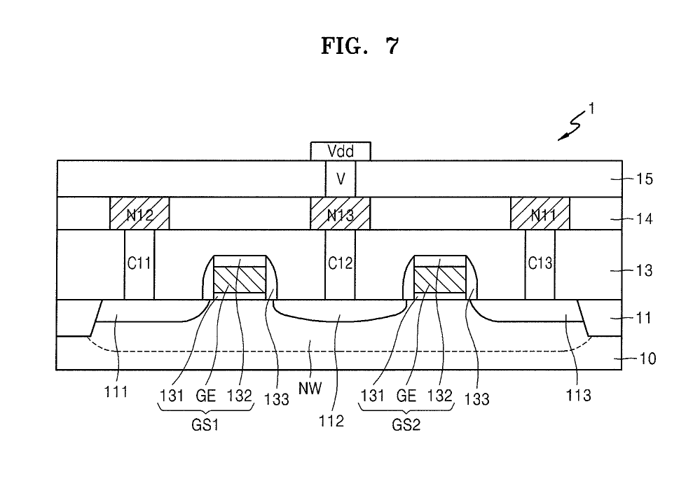

FIG. 7 is a cross-sectional view of the semiconductor memory device 1 of FIG. 1, taken along line II-II′. Referring to FIG. 7, the semiconductor memory device 1 is formed on the substrate 10 having the N well region NW. The N well region NW is defined by the isolation layer 11 formed on the substrate 10.

First and second gate stacks GS1 and GS2 are disposed on the N well region NW. Each of the first and second gate stacks GS1 and GS2 may include a gate insulating layer 131, a gate electrode layer GE, and a capping layer 132. Specifically, each of the first and second gate stacks GS1 and GS2 may be formed by sequentially forming the gate insulating layer 131, the gate electrode layer GE, and the capping layer 132 on the N well region NW and then patterning the resultant structure.

The gate insulating layer 131 may be a silicon oxide layer but is not limited thereto. For example, the gate insulating layer 131 may include a high k-dielectric thin film, which has a higher dielectric constant than a silicon oxide layer, e.g., a silicon nitride layer (SiNx), a tantalum oxide layer (TaOx), a hafnium oxide layer (HfOx), an aluminum oxide layer (AlOx), or a zinc oxide layer (ZnOx). The gate electrode layer GE may be, for example, a high-density doped poly-silicon layer, a metal layer formed of at least one metal selected from the group consisting of tungsten, nickel, molybdenum, and cobalt, a metal silicide layer, or combinations thereof. For example, the gate electrode layer GE may be a stacked layer of the high-density doped poly-silicon layer and a nickel-cobalt silicide layer. The capping layer 132 may be a silicon nitride layer or a silicon oxide layer.

Spacers 133 are disposed on sidewalls of the first and second gate stacks GS1 and GS2, respectively. The spacers 133 may be formed of a silicon nitride. Source and drain regions 111, 112, and 113 are disposed beside the first and second gate stacks GS1 and GS2 in the N well region NW, respectively. For example, the source and drain regions 111, 112, and 113 may be formed by implanting high-density ions into the N well region NW by using the spacers 133 as ion implantation masks.

The first insulating layer 13 is disposed on the first and second gate stacks GS1 and GS2, and the first to third contact plugs C11, C12, and C13 are disposed on the first insulating layer 13. The first to third contact plugs C11, C12, and C13 are connected to the source and drain regions 111, 112, and 113, respectively. Although not shown, a silicide layer may be formed on the source and drain regions 111, 112, and 113.

The second insulating layer 14 is disposed on the first insulating layer 13, and the first to third metallic interconnection layers N11 to N13 are disposed on the second insulating layer 14. The third insulating layer 15 is disposed on the second insulating layer 14, and the via plug V is disposed on the third insulating layer 15. The power supply voltage line Vdd is disposed on the via plug V.

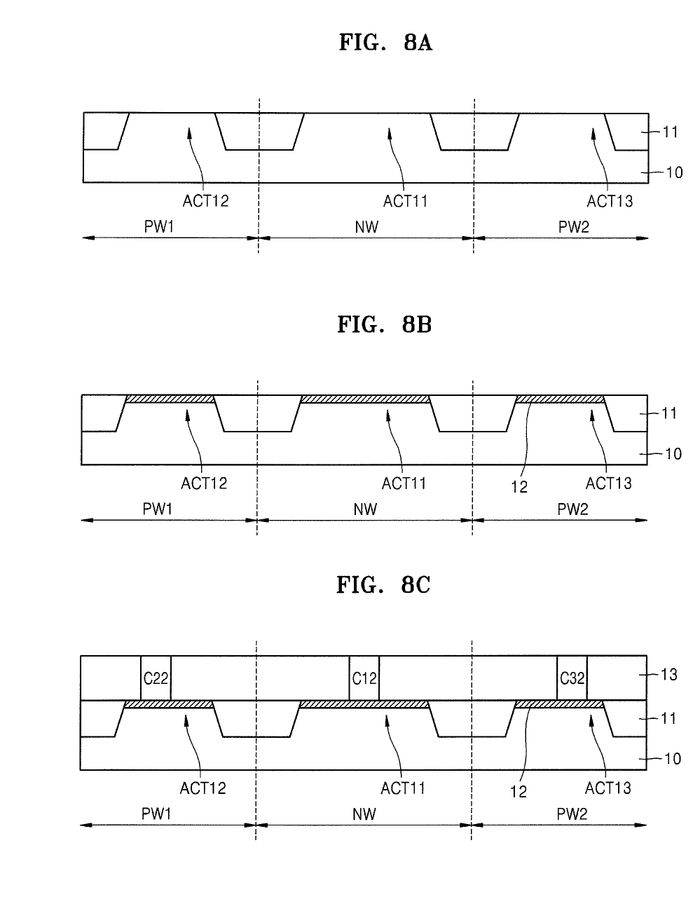

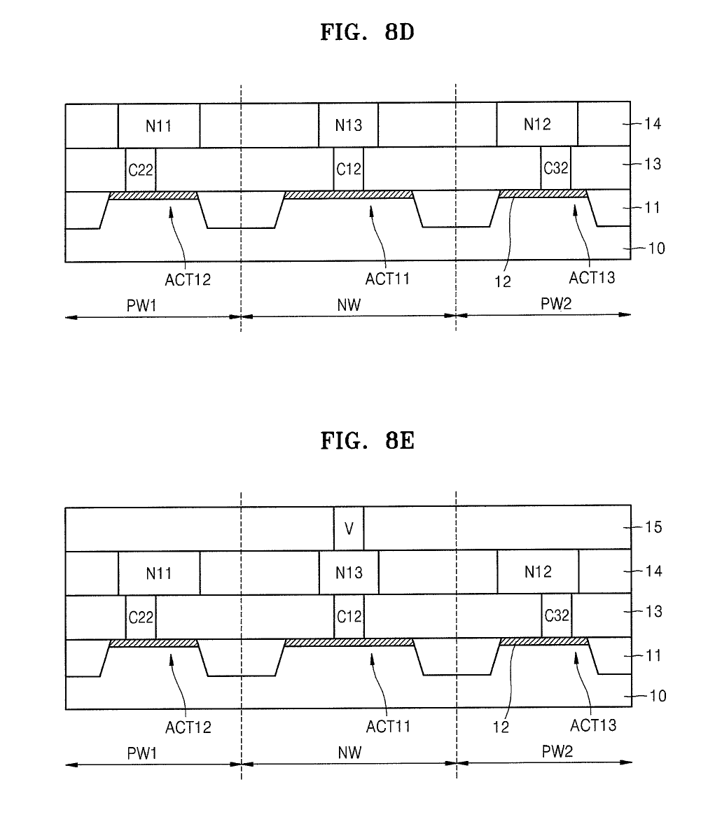

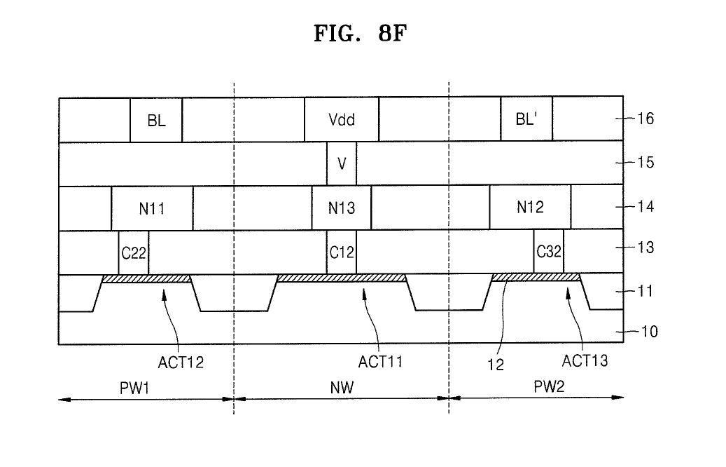

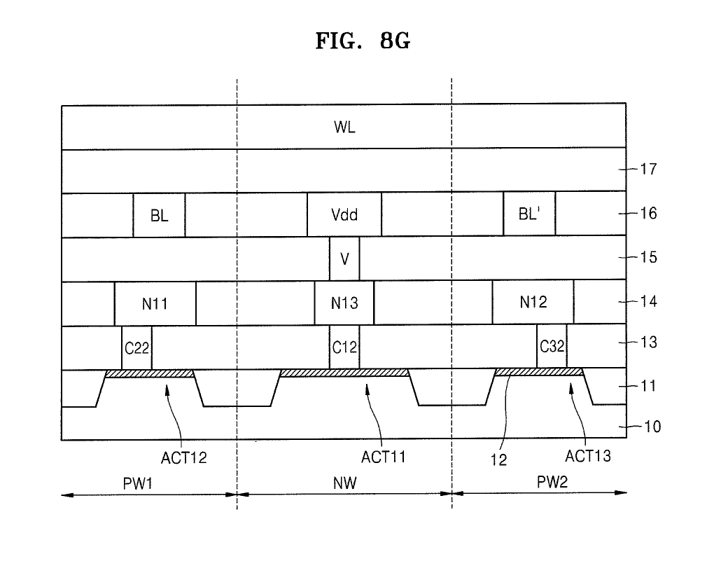

FIGS. 8A to 8G are cross-sectional views illustrating a method of manufacturing a semiconductor memory device, according to an exemplary embodiment of the inventive concept. Referring to FIG. 8A, a substrate 10 includes an N well region NW in which PMOS transistors are to be formed, and first and second P well regions PW1 and PW2 in which NMOS transistors are to be formed. A first active region ACT11 is formed in the N well region NW, and second and third active regions ACT12 and ACT13 are formed in the first and second P well regions PW1 and PW2, respectively. The first to third active regions ACT11, ACT12, and ACT13 may be defined by an isolation layer 11, such as an STI layer.

Referring to FIG. 8B, a silicide layer 12 is formed on the first to third active regions ACT11, ACT12, and ACT13. Specifically, the silicide layer 12 may be formed on the first to third active regions ACT11, ACT12, and ACT13 by forming a metal layer (not shown) on the substrate 10 and thermally processing the resultant substrate 10. If the silicide layer 12 is formed as described above, then contact resistance among the first to third active regions ACT11, ACT12, and ACT13 and contact plugs that are to be formed may be reduced.

Referring to FIG. 8C, a first insulating layer 13 is formed on the substrate 10. Next, a mask layer is formed on the first insulating layer 13 according to a photolithography process to expose a region where a plurality of first contact holes (not shown) are to be formed. Next, first contact holes (not shown) are formed in the first insulating layer 13 according to a dry etching process and then are filled with a metal material, thereby forming fifth, second and eighth contact plugs C22, C12, and C32. Here, the fifth, second and eighth contact plugs C22, C12, and C32 may be formed of at least one metal selected from the group consisting of tungsten (W), aluminum (Al), copper (Cu), molybdenum (Mo), titanium (Ti), tantalum (Ta), and ruthenium (Ru), but an exemplary embodiment of the inventive concept is not limited thereto and the contact plugs C22, C12, and C32 may be conductive nitrides of at least one metal selected from the above group.

Referring to FIG. 8D, a second insulating layer 14 is formed on the first insulating layer 13. Next, a plurality of second contact holes (not shown) may be formed in the second insulating layer 14 and then may be filled with a metal material, thereby forming a first metallic interconnection layer N11, a second metallic interconnection layer N12, and a third metallic interconnection layer N13.

Referring to FIG. 8E, a third insulating layer 15 is formed on the second insulating layer 14. Next, a third contact hole (not shown) may be formed in the third insulating layer 15 and may then be filled with a metal material, thereby forming a via plug V. The via plug V may be formed of at least one metal selected from the group consisting of tungsten (W), aluminum (Al), copper (Cu), molybdenum (Mo), titanium (Ti), tantalum (Ta), and ruthenium (Ru), but an exemplary embodiment of the inventive concept is not limited thereto and the via plug V may be a conductive nitride of at least one metal selected from this group.

Referring to FIG. 8F, a fourth insulating layer 16 is formed on the third insulating layer 15. Next, a plurality of fifth contact holes (not shown) may be formed in the fourth insulating layer 16 and may then be filled with a metal material, thereby forming a bit line BL, a power supply voltage line Vdd, and a complementary bit line BL′. In another exemplary embodiment of the inventive concept, the bit line BL and the complementary bit line BL′ may be formed on a layer on which the power supply voltage line Vdd is not formed. In another exemplary embodiment of the inventive concept, the bit line BL, the complementary bit line BL′, and the power supply voltage line Vdd may be formed below the first to third metallic interconnection layers N11, N12, and N13, respectively.

Referring to FIG. 8G, a fifth insulating layer 17 and a word line WL are sequentially formed on the fourth insulating layer 16. In another exemplary embodiment of the inventive concept, the word line WL may be formed below the bit line BL and the complementary bit line BL′. In another exemplary embodiment of the inventive concept, the word line WL may be formed below the first to third metallic interconnection layers N11, N12, and N13.

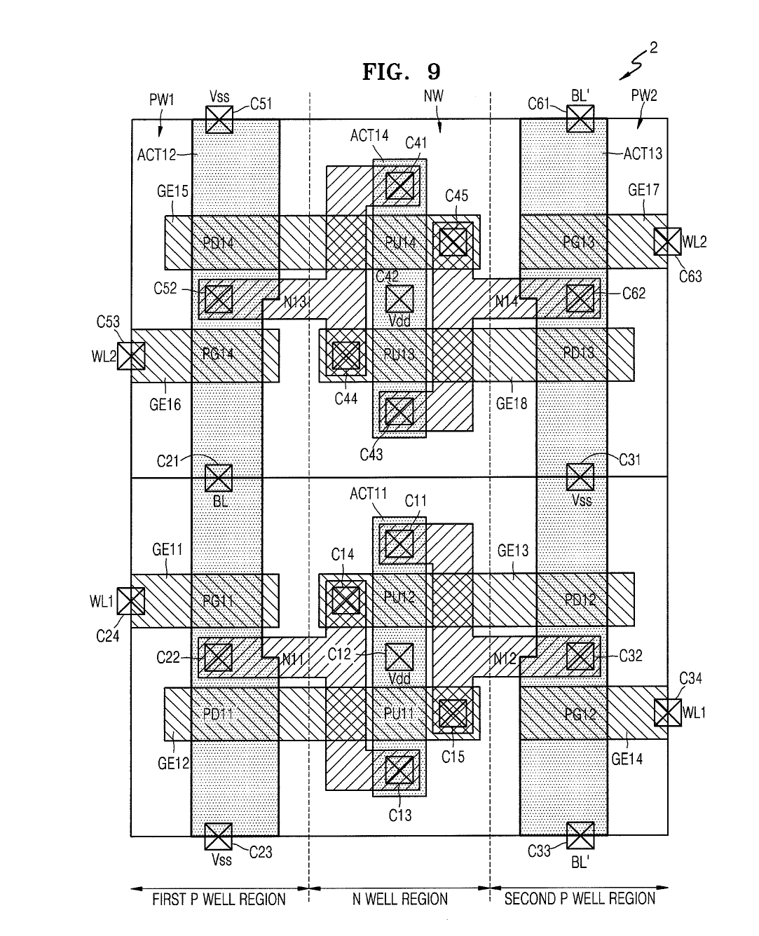

FIG. 9 is a layout diagram of a semiconductor memory device 2 according to an exemplary embodiment of the inventive concept. Referring to FIG. 9, the semiconductor memory device 2 includes two SRAM cells formed on a substrate, in which a first well region NW, and a second well region PW1 and a third well region PW2 having the first well region NW therebetween are defined. The first well region NW may be a first conductive type, and the second and third well regions PW1 and PW2 may be a second conductive type. In the current embodiment, the first conductive type may be an N type and the second conductive type may be a P type. It is assumed that the first well region NW is an N well region NW, the second well region PW1 is a first P well region PW1, and the third well region PW2 is a second P well region PW2. The semiconductor memory device 2 according to the current embodiment is a modified example of the semiconductor memory device 1 described above with reference to FIGS. 1 to 8. Thus, the operation and structure of the semiconductor memory device 2 that are the same as those of the semiconductor memory device 1 will not be described again here.

In the N well region NW, an N type well is formed in the substrate, for example, through ion implantation. The N well region NW includes a first active region ACT11 and a fourth active region ACT14 that are defined by an isolation layer. In the current embodiment, each of the first and fourth active regions ACT11 and ACT14 may be one bar-type active region formed to be long in the vertical direction.

In this case, a P type diffusion region may be obtained by doping P+ type impurities onto the first active region ACT11, and contact plugs C11, C12, and C13 may be formed in the first active region ACT11. In the first active region ACT11, two pull-up devices may be formed in a line. In the current embodiment, the two pull-up devices may be first and second PMOS transistors PU11 and PU12. In addition, a P type diffusion region may be obtained by doping P+ type impurities onto the fourth active region ACT14, and contact plugs C41, C42, and C43 may be formed in the fourth active region ACT14. In the fourth active region ACT14, two pull-up devices may be formed in a line. In the current embodiment, the two pull-up devices may be third and fourth PMOS transistors PU13 and PU14.

In the first P well region PW1, a P type well is formed in the substrate, for example, through ion implantation. The first P well region PW1 includes a second active region ACT12 defined by an isolation layer. In the current embodiment, the second active regions ACT12 may be one active region that extends in parallel with the first and fourth active regions ACT11 and ACT14.

In this case, an N type diffusion region may be obtained by doping N+ type impurities onto the second active region ACT12, and contact plugs C21, C22, C23, C51, C52, and C53 may be formed in the second active region ACT12. In the second active region ACT12, two pull-down devices and two access devices may be formed. In the current embodiment, the two pull-down devices may be first and sixth NMOS transistors PD11 and PD14 and the two access devices may be third and eighth NMOS transistors PG11 and PG14.

In the second P well region PW2, a P type well is formed in the substrate, for example, through ion implantation. The second P well region PW2 includes a third active region ACT13 defined by an isolation layer. In the current embodiment, the third active region ACT13 may be one active region that extends in parallel with the first and fourth active regions ACT11 and ACT14. In this case, an N type diffusion region may be obtained by doping N+ type impurities onto the third active region ACT13, and contact plugs C31, C32, C33, C61, and C62 may be formed in the third active region ACT13. In the third active region ACT13, two pull-down devices and two access devices may be formed. In the current embodiment, the two pull-down devices may be second and fifth NMOS transistors PD12 and PD13 and the two access devices may be fourth and seventh NMOS transistors PG12 and PG13.

First to eighth gate electrodes GE11, GE12, GE13, GE14, GE15, GE16, GE17, and GE18 are formed on the substrate having the first to fourth active regions ACT11 to ACT14. Specifically, the first gate electrode GE11 is disposed to cross the second active region ACT12, the second gate electrode GE12 is disposed to cross the first and second active regions ACT11 and ACT12, the third gate electrode GE13 is disposed to cross the first and third active regions ACT11 and ACT13, and the fourth gate electrode GE14 is disposed to cross the third active region ACT13. The fifth gate electrode GE15 is disposed to cross the second and fourth active regions ACT12 and ACT14, the sixth gate electrode GE16 is disposed to cross the second active region ACT12, the seventh gate electrode GE17 is disposed to cross the third active region ACT13, and the eighth gate electrode GE18 is disposed to cross the fourth and third active regions ACT14 and ACT13. In this case, word line contact plugs C24, C34, C63, and C53 are formed on the first, fourth, sixth and seventh gate electrodes GE11, GE14, GE16, and GE17, respectively, and interconnection contact plugs C15, C14, C45, and C44 are formed on the second, third, fifth and eighth gate electrodes GE12, GE13, GE15, and GE18, respectively.

First to fourth metallic interconnection layers N11, N12, N13, and N14 are formed on the substrate on which the first to eighth gate electrodes GE11, GE12, GE13, GE14, GE15, GE16, GE17, and GE18 are formed. The first metallic interconnection layer N11 connects the contact plug C13 formed on the first active region ACT11, the contact plug C22 formed on the second active region ACT12, and the interconnection contact plug C14 formed on the third gate electrode GE13 with one another. The second metallic interconnection layer N12 connects the contact plug C11 formed on the first active region ACT11, the contact plug C32 formed on the third active region ACT13, and the interconnection contact plug C15 formed on the second gate electrode GE12 with one another. The third metallic interconnection layer N13 connects the contact plug C41 formed on the fourth active region ACT14, the contact plug C52 formed on the second active region ACT12, and the interconnection contact plug C44 formed on the eighth gate electrode GE18 with one another. The fourth metallic interconnection layer N14 connects the contact plug C43 formed on the fourth active region ACT14, the contact plug C62 formed on the third active region ACT13, and the interconnection contact plug C45 formed on the fifth gate electrode GE15 with one another.

In the semiconductor memory device 2 according to the current embodiment, the first NMOS transistor PD11, the first PMOS transistor PU11, and the fourth NMOS transistor PG12 may be horizontally arranged in a line, the third NMOS transistor PG11, the second PMOS transistor PU12, and the second NMOS transistor PD12 may be horizontally arranged in a line, the eighth NMOS transistor PG14, the third PMOS transistor PU13, and the fifth NMOS transistor PD13 may be horizontally arranged in a line, and the sixth NMOS transistor PD14, the fourth PMOS transistor PU14, and the seventh NMOS transistor PG13 may be horizontally arranged in a line.

In addition, in the semiconductor memory device 2, the first, third, eighth, and sixth NMOS transistors PD11, PG11, PG14, and PD14 may be vertically arranged in a line in the first P well region PW1, the first to fourth PMOS transistors PU11, PU12, PU13, and PU14 may be vertically arranged in a line in the N well region NW, and the fourth, second, fifth, and seventh NMOS transistors PG12, PD12, PD13, and PG13 may be vertically arranged in a line in the second P well region PW2.

As described above, in the semiconductor memory device 2, the first to fourth NMOS transistors PD11, PD12, PG11, and PG12 are arranged to be horizontally symmetrical with respect to the first and second PMOS transistors PU11 and PU12, and the fifth to eighth NMOS transistors PD13, PD14, PG13, and PG14 are arranged to be horizontally symmetrical with respect to the third and fourth PMOS transistors PU3 and PU4. Thus, the horizontal and vertical lengths of a unit cell in the semiconductor memory device 2 may decrease, thereby improving the integration degree of the semiconductor memory device 2. In addition, if a plurality of unit cells is arranged in the semiconductor memory device 2, an additional region is not required to be included in a boundary region.

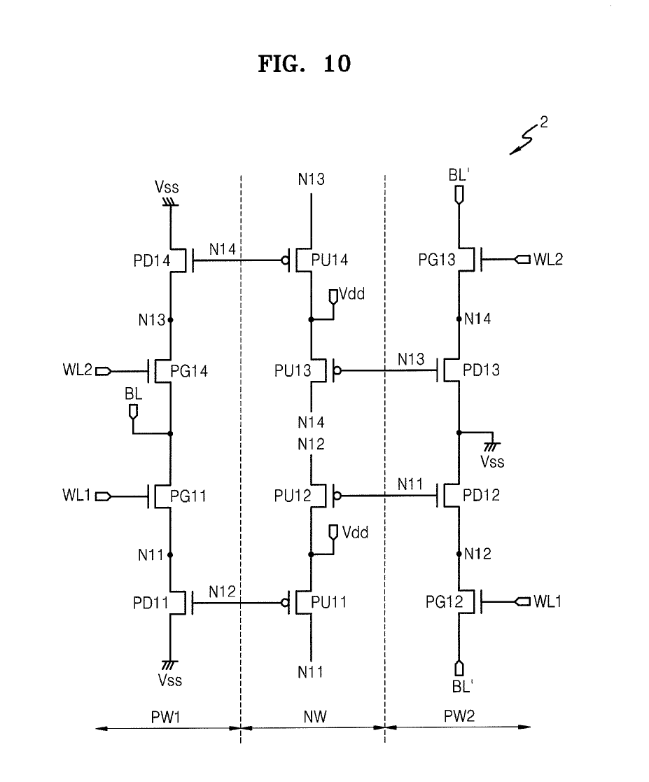

FIG. 10 is a circuit diagram of an equivalent circuit of the semiconductor memory device 2 of FIG. 9, according to an exemplary embodiment of the inventive concept. Referring to FIG. 10, the semiconductor memory device 2 includes first, third, sixth and eighth NMOS transistors PD11, PG11, PD14, and PG14 disposed in a first P well region PW1, first to fourth PMOS transistors PU11, PU12, PU13, and PU14 disposed in an N well region NW, and second, fourth, fifth and seventh NMOS transistors PD12, PG12, PD13, and PG13 disposed in a second P well region PW2. The first PMOS transistor PU11 and the first NMOS transistor PD11 form a first inverter. The second PMOS transistor PU12 and the second NMOS transistor PD12 form a second inverter. The third PMOS transistor PU13 and the fifth NMOS transistor PD13 form a third inverter. The fourth PMOS transistor PU14 and the sixth NMOS transistor PD14 form a fourth inverter.

The third NMOS transistor PG11 may be switched on or off according to a voltage applied to a word line WL1 and may connect a bit line BL to a first node N11. The first node N11 corresponds to the first metallic interconnection layer N11 of FIG. 9. In detail, if the voltage applied to the word line WL1 is logic ‘1’, then the third NMOS transistor PG11 may be turned on to connect the bit line BL to the first node N11. The first node N11 is connected to input terminals of the second inverter, e.g., gates of the respective second PMOS transistor PU12 and second NMOS transistor PD12, and is also connected to output terminals of the first inverter, e.g., drains of the respective first PMOS transistor PU11 and first NMOS transistor PD11.

The fourth NMOS transistor PG12 may be switched on or off according to a voltage applied to the word line WL1 and may connect a complementary bit line BL′ to a second node N12. The second node N12 corresponds to the second metallic interconnection layer N12 of FIG. 9. In detail, if the voltage applied to the word line WL1 is logic ‘1’, then the fourth NMOS transistor PG12 may be turned on to connect the complementary bit line BL′ to the second node N12. The second node N12 is connected to input terminals of the first inverter, e.g., gates of the respective first PMOS transistor PU11 and first NMOS transistor PD11, and is also connected to output terminals of the second inverter, e.g., drains of the respective second PMOS transistor PU12 and second NMOS transistor PD12.

The seventh NMOS transistor PG13 may be switched on or off according to a voltage applied to a word line WL2 and may connect the complementary bit line BL′ to a fourth node N14. The fourth node N14 corresponds to the fourth metallic interconnection layer N14 of FIG. 9. Specifically, if the voltage applied to the word line WL2 is logic ‘1’ then the seventh NMOS transistor PG13 may be turned on to connect the complementary bit line BL′ to the fourth node N14. The fourth node N14 is connected to input terminals of the fourth inverter, e.g., gates of the respective fourth PMOS transistor PU14 and sixth NMOS transistor PD14, and is also connected to output terminals of the third inverter, e.g., drains of the respective third PMOS transistor PU13 and fifth NMOS transistor PD13.

The eighth NMOS transistor PG14 may be switched on or off according to a voltage applied to the word line WL2 and may connect the bit line BL to a third node N13. The third node N13 may correspond to the third metallic interconnection layer N13 of FIG. 9. In detail, if the voltage applied to the word line WL2 is logic ‘1’, then the eighth NMOS transistor PG14 may be turned on to connect the bit line BL to the third node N13. The third node N13 is connected to input terminals of the third inverter, e.g., gates of the respective third PMOS transistor PU13 and fifth NMOS transistor PD13, and is also connected to output terminals of the fourth inverter, e.g., drains of the respective fourth PMOS transistor PU14 and sixth NMOS transistor PD14.

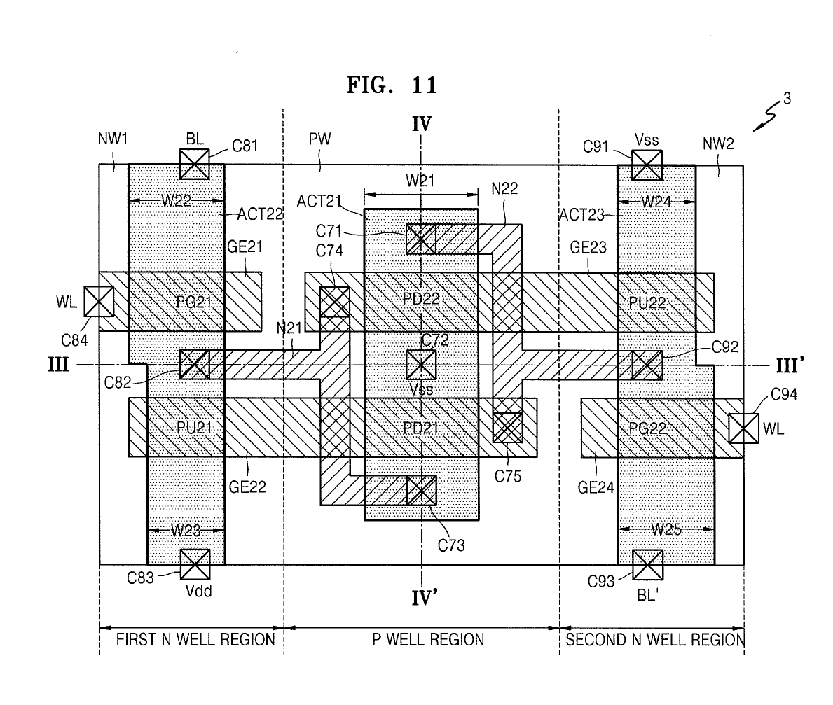

FIG. 11 is a layout diagram of a semiconductor memory device 3 according to an exemplary embodiment of the inventive concept. Referring to FIG. 11, the semiconductor memory device 3 may include an SRAM cell formed on a substrate, in which a first well region PW and a second well region NW1 and a third well region NW2 having the first well region PW therebetween are defined. The first well region PW may be a first conductive type, and the second and third well regions NW1 and NW2 may be a second conductive type. In the current embodiment, the first conductive type may be a P type and the second conductive type may be an N type. Hereinafter, it is assumed that the first well region PW is a P well region PW, the second well region NW1 is a first N well region NW1, and the third well region is a second N well region NW2.

The P well region PW is a region in which a P type well is formed, for example, through ion implantation. The P well region PW includes a first active region ACT21 defined by an isolation layer. In the current embodiment, the first active region ACT21 may be one bar-type active region formed to be long in the vertical direction. An N type diffusion region may be formed by doping N+ type impurities onto the first active region ACT21. In addition, first to third contact plugs C71, C72, and C73 may be formed in the first active region ACT21.

In the first active region ACT21, two pull-down devices may be formed in a line. In the current embodiment, the two pull-down devices may be first and second NMOS transistors PD21 and PD22.

If the two pull-down devices, e.g., the first and second NMOS transistors PD21 and PD22 are disposed in the first active region ACT21 which is one active region as described above, a mismatch between the first and second NMOS transistors PD21 and PD22 may be reduced. Specifically, a dispersion between a threshold voltage of the first NMOS transistor PD21 and a threshold voltage of the second NMOS transistor PD22 may be reduced.

The first N well region NW1 is a region in which an N type well is formed, for example, through ion implantation. The first N well region NW1 includes a second active region ACT22 defined by an isolation layer. In the current embodiment, the second active region ACT22 may be one active region extending in parallel with the first active region ACT21. In this case, a P type diffusion region may be formed by doping P+ type impurities onto the second active region ACT22. In addition, fourth to sixth contact plugs C81, C82, and C83 may be formed in the second active region ACT22. In the second active region ACT22, one pull-up device and one access device may be formed. In the current embodiment, the pull-up device may be a first PMOS transistor PU21 and the access device may be a third PMOS transistor PG21.

The second N well region NW2 is a region in which an N type well is formed, for example, through ion implantation. The second N well region NW2 includes a third active region ACT23 defined by an isolation layer. In the current embodiment, the third active region ACT23 may be one active region extending in parallel with the first active region ACT21. In this case, a P type diffusion region may be formed by doping P+ type impurities onto the third active region ACT23. In addition, seventh to ninth contact plugs C91, C92, and C93 may be formed in the third active region ACT23. In the third active region ACT23, one pull-up device and one access device may be formed. In the current embodiment, the pull-up device may be a second PMOS transistor PU22 and the access device may be a fourth PMOS transistor PG22.

As described above, according to the current embodiment, the semiconductor memory device 3 may include a plurality of access devices, e.g., the third and fourth PMOS transistors PG21 and PG22. The plurality of access devices may include PMOS transistors instead of NMOS transistors in the semiconductor memory device 3.

The widths of the first to third active regions ACT21, ACT22, and ACT23 will now be compared with one another. The first active region ACT21 may have a uniform width, e.g., a first width W21. A width of the second active region ACT22 may not be uniform. Particularly, a second width W22 of a part of the second active region ACT22 in which the third PMOS transistor PG21 is disposed, may be greater than a third width W23 of the other part of the second active region ACT22 in which the first PMOS transistor PU21 is disposed. The second and third widths W22 and W23 may be less than the first width W21. A width of the third active region ACT23 may not also be uniform. Particularly, a fourth width W24 of a part of the third active region ACT23 in which the second PMOS transistor PU22 is disposed, may be less than a fifth width W25 of the other part of the third active region ACT23 in which the fourth PMOS transistor PG22 is disposed. The fourth and fifth widths W24 and W25 may be less than the first width W21. In addition, the fourth width W24 may be substantially the same as the third width W23, and the fifth width W25 may be substantially the same as the second width W22.

If the first width W21 of the first active region ACT21 in which the first and second NMOS transistors PD21 and PD22 are formed is greater than the other widths W22, W23, W24, and W25 as described above, then the speed of performing a pull-down operation with the first and second NMOS transistors PD21 and PD22 may increase. In addition, if the second and fifth widths W22 and W25 of the second and third active regions ACT22 and ACT23 in which the third and fourth PMOS transistors PG21 and PG22 are formed, respectively, are greater than the third and fourth widths W23 and W24 of the second and third active regions ACT22 and ACT23 in which the first and second PMOS transistors PU21 and PU22 are formed, respectively, then the speed of performing a write operation on the semiconductor memory device 3 may increase.

First to fourth gate electrodes GE21, GE22, GE23, and GE24 are formed on the substrate in which the first to third active regions ACT21, ACT22, and ACT23 are defined. Specifically, the first gate electrode GE21 is disposed to cross the second active region ACT22, the second gate electrode GE22 is disposed to cross the first and second active regions ACT21 and ACT22, the third gate electrode GE23 is disposed to cross the first and third active regions ACT21 and ACT23, and the fourth gate electrode GE24 is disposed to cross the third active region ACT23. Word line contact plugs C84 and C94 are formed on the first and fourth gate electrodes GE21 and GE24, respectively. Interconnection contact plugs C75 and C74 are formed on the second and third gate electrodes GE22 and GE23, respectively.

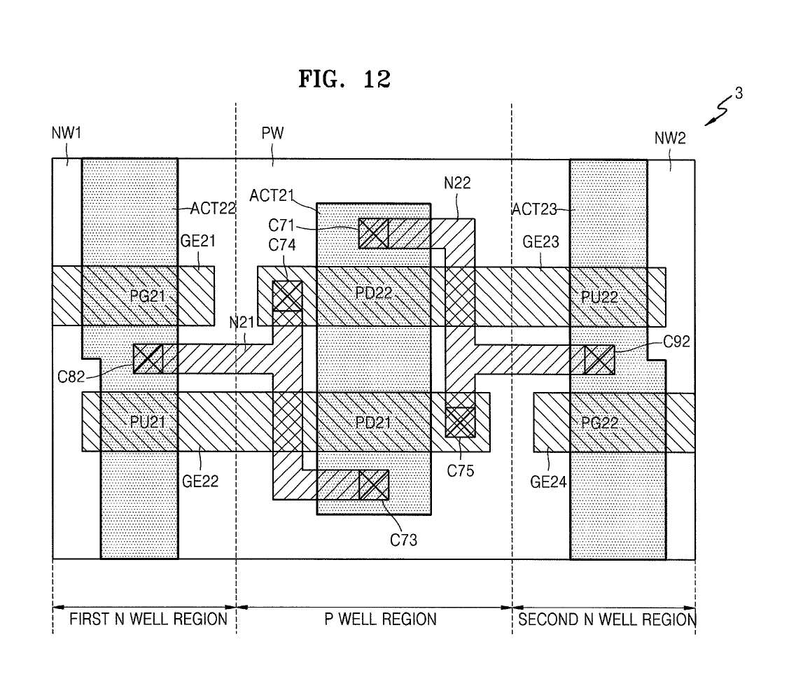

FIG. 12 is a layout diagram schematically illustrating first and second metallic interconnection layers N21 and N22 of the semiconductor memory device 3 of FIG. 11, according to an exemplary embodiment of the inventive concept. Referring to FIG. 12, the first and second metallic interconnection layers N21 and N22 are formed on the substrate having the first to fourth gate electrodes GE21 to GE24. The first metallic interconnection layer N21 connects third contact plug C73 on the first active region ACT21, the fifth contact plug C82 on the second active region ACT22, and the interconnection contact plug C74 on the third gate electrode GE23 to one another. The second metallic interconnection layer N22 connects the first contact plug C71 on the first active region ACT21, the eighth contact plug C92 on the third active region ACT23, and the interconnection contact plug C75 the second gate electrode GE22 to one another.

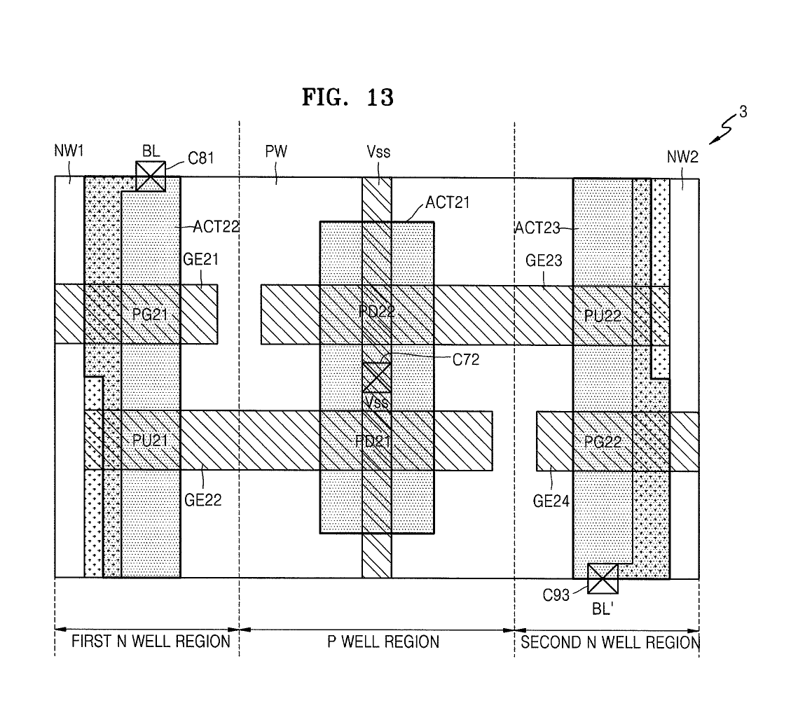

FIG. 13 is a layout diagram schematically illustrating bit line interconnection layers of the semiconductor memory device 3 of FIG. 11, according to an exemplary embodiment of the inventive concept. Referring to FIG. 13, a pair of a bit line BL and a complementary bit line BL′ are formed on the substrate having the first and second metallic interconnection layers N21 and N22. The bit line BL and the complementary bit line BL′ may extend to be parallel with the first to third active regions ACT21, ACT22, and ACT23. In this case, the bit line BL is connected to the second active region ACT22 via the fourth contact plug C81 formed in the second active region ACT22, and the complementary bit line BL′ is connected to the third active region ACT23 via the ninth contact plug C93 formed in the third active region ACT23.

In addition, a ground voltage line Vss is formed on the substrate having the first and second metallic interconnection layers N21 and N22. The ground voltage line Vss may be disposed between the pair of bit lines BL and BL′ and may extend in parallel with the pair of bit lines BL and BL′. The ground voltage line Vss is connected to the first active region ACT21 via the second contact plug C72 formed in the first active region ACT21.

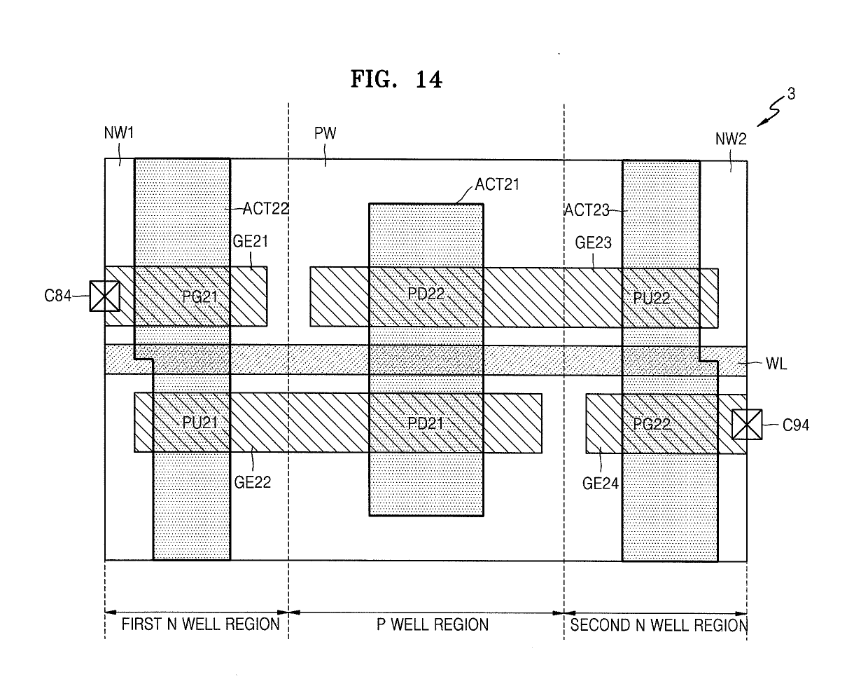

FIG. 14 is a layout diagram schematically illustrating word line interconnection layers of the semiconductor memory device 3 of FIG. 11, according to an exemplary embodiment of the inventive concept. Referring to FIG. 14, a word line WL is formed on the substrate having the pair of bit lines BL and BL′. The word line WL may extend in parallel with the first to fourth gate electrodes GE21, GE22, GE23, and GE24. The word line WL is connected to the first and fourth gate electrodes GE21 and GE24 via the word line contact plugs C84 and C94, respectively. Although not shown, a metallic interconnection layer may further be formed to connect the word line WL to the word line contact plugs C84 and C94.

In the current embodiment, the word line WL is disposed on the pair of bit lines BL and BL′, but an exemplary embodiment of the inventive concept is not limited thereto and the pair of bit lines BL and BL′ may be formed on the word line WL.

Referring back to FIG. 11, the first NMOS transistor PD21 is defined by the second gate electrode GE22 on the first active region ACT21 and the second and third contact plugs C72 and C73 having the second gate electrode GE2 therebetween in the first active region ACT21. Here, the second contact plug C72, the second gate electrode GE22, and the third contact plug C73 correspond to a source, gate, and drain of the first NMOS transistor PD21, respectively.

The first PMOS transistor PU21 is defined by the second gate electrode GE22 on the second active region ACT22 and the fifth and sixth contact plugs C82 and C83 having the second gate electrode GE22 therebetween in the second active region ACT22. Here, the fifth contact plug C82, the second gate electrode GE22, and the sixth contact plug C83 correspond to a drain, gate, and source of the first PMOS transistor PU21, respectively.

The second NMOS transistor PD22 is defined by the third gate electrode GE23 on the first active region ACT21 and the first and second contact plugs C71 and C72 having the third gate electrode GE23 therebetween in the first active region ACT21. Here, the first contact plug C71, the third gate electrode GE23, and the second contact plug C72 correspond to a drain, gate, and source of the second NMOS transistor PD22, respectively.

The second PMOS transistor PU22 is defined by the third gate electrode GE23 on the third active region ACT23 and the seventh and eighth contact plugs C91 and C92 having the third gate electrode GE23 therebetween in the third active region ACT23. Here, the seventh contact plug C91, the third gate electrode GE23, and the eighth contact plug C92 correspond to a source, gate, and drain of the second PMOS transistor PU22, respectively.

In this case, the first NMOS transistor PD21 and the first PMOS transistor PU21 are commonly connected to the second gate electrode GE22, and are connected via the second metallic interconnection layer N22, thereby forming a first inverter. The second NMOS transistor PD22 and the second PMOS transistor PU22 are commonly connected to the third gate electrode GE23, and are connected via the first metallic interconnection layer N21, thereby forming a second inverter. In the semiconductor memory device 3, the first and second inverters form a latch for storing data.

The third PMOS transistor PG21 is defined by the first gate electrode GE21 on the second active region ACT22 and the fourth and fifth contact plugs C81 and C82 having the first gate electrode GE21 therebetween in the second active region ACT22. Here, the fourth and fifth contact plugs C81 and C82 correspond to a drain and source of the third PMOS transistor PG21, respectively, and the first gate electrode GE21 corresponds to a gate of the third PMOS transistor PG21. In this case, the fourth contact plug C81 is connected to the bit line BL, and the word line contact plug C84 on the first gate electrode GE21 is connected to the word line WL. The third PMOS transistor PG21 may act as a first pass gate or a first transmission gate.

The fourth PMOS transistor PG22 is defined by the fourth gate electrode GE24 on the third active region ACT23 and the eighth and ninth contact plugs C92 and C93 having the fourth gate electrode GE24 therebetween in the third active region ACT23. Here, the eighth and ninth contact plugs C92 and C93 correspond to a source and drain of the fourth PMOS transistor PG22, respectively, and the fourth gate electrode GE24 corresponds to a gate of the fourth PMOS transistor PG22. The ninth contact plug C93 is connected to the complementary bit line BL′, and the word line contact plug C94 on the fourth gate electrode GE24 is connected to the word line WL. The fourth PMOS transistor PG22 may act as a second pass gate or a second transmission gate.

In the semiconductor memory device 3 according to the current embodiment, the first and second NMOS transistors PD21 and PD22 are disposed in a line in the first active region ACT21 which is one active region. Thus, a patterning process does not need to be performed to separately form an active region for each of the first and second NMOS transistors PD21 and PD22. Instead, a patterning process may be performed to form only the first active region ACT21. Since only one active region, e.g., the first active region ACT21, is formed for the first and second NMOS transistors PD21 and PD22 rather than two active regions, there is no need to form an isolation layer between two active regions. Accordingly, the length of a unit cell of the semiconductor memory device 3 in the horizontal direction is less than that when two active regions are formed, thereby improving the integration degree of the semiconductor memory device 3.

In addition, in the semiconductor memory device 3 according to the current embodiment, the first and second NMOS transistors PD21 and PD22 in the first active region ACT21 share the second contact plug C72 connected to the ground voltage line Vss. Thus, two contact plugs do not need to be formed to apply a ground voltage Vss to the first and second NMOS transistors PD21 and PD22. Therefore, the length of a unit cell of the semiconductor memory device 3 in the vertical direction is less than that when two contact plugs are formed, thereby improving the integration degree of the semiconductor memory device 3.

Furthermore, in the semiconductor memory device 3 according to the current embodiment, the first to third active regions ACT21, ACT22, and ACT23 are disposed to be parallel with one another, the first PMOS transistor PU21 is disposed in a location corresponding to the first NMOS transistor PD21 and the third PMOS transistor PG21 is disposed in a location corresponding to the second NMOS transistor PD22 in the second active region ACT22, and the fourth PMOS transistor PG22 is disposed in a location corresponding to the first NMOS transistor PD21 and the second PMOS transistor PU22 is disposed in a location corresponding to the second NMOS transistor PD22 in the third active region ACT23. As described above, in a unit cell of the semiconductor memory device 3, transistors are disposed to be symmetrical with respect to the first and second NMOS transistors PD21 and PD22, thereby improving the integration degree of the semiconductor memory device 3. In addition, if a plurality of unit cells is disposed in the semiconductor memory device 3, an additional region is not required to be included in a boundary region.

As described above, according to the current embodiment, in the semiconductor memory device 3, N channel transistors may be formed and P channel transistors or other devices may be formed to be symmetrical with respect to the P channel transistors, in one active region. In the current embodiment, the semiconductor memory device 3 includes six transistors, but an exemplary embodiment of the inventive concept is not limited thereto and the semiconductor memory device 3 may include four transistors and two resistive devices. Further, the semiconductor memory device 3 may include may include more than six transistors or less than six transistors.

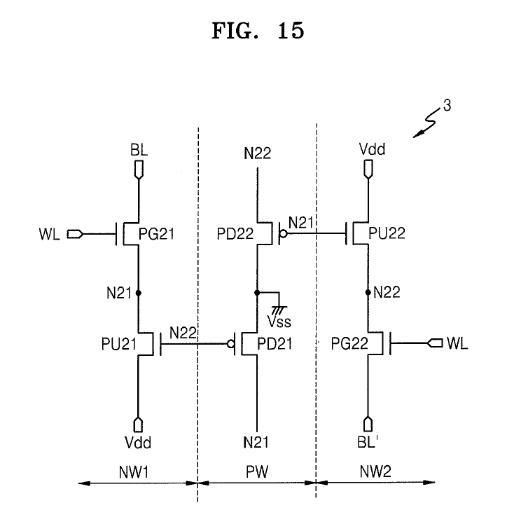

FIG. 15 is a circuit diagram of an equivalent circuit of the semiconductor memory device 3 of FIG. 1, according to an exemplary embodiment of the inventive concept. Referring to FIG. 15, the semiconductor memory device 3 includes the first and third PMOS transistors PU21 and PG21 disposed in the first N well region NW1, the first and second NMOS transistors PD21 and PD22 disposed in the P well region PW, and the second and fourth PMOS transistors PU22 and PG22 disposed in the second N well region NW2. In this case, the first NMOS transistor PD21 and the first PMOS transistor PU21 form a first inverter, and the second NMOS transistor PD22 and the second PMOS transistor PU22 form a second inverter.

The third PMOS transistor PG21 may be switched on or off according to a voltage applied to the word line WL and may connect the bit line BL to a first node N21. The first node N21 corresponds to the first metallic interconnection layer N21 of FIG. 11. In detail, if the voltage applied to the word line WL is logic ‘0’, then the third PMOS transistor PG21 may be turned on to connect the bit line BL to the first node N21. The first node N21 is connected to input terminals of the second inverter, e.g., the gates of the second NMOS transistor PD22 and the second PMOS transistor PU22, and is connected to output terminals of the first inverter, e.g., the drains of the first NMOS transistor PD21 and the first PMOS transistor PU21.

The fourth PMOS transistor PG22 may be switched on or off according to the voltage applied to the word line WL and may connect the complementary bit line BL′ to a second node N22. The second node N22 corresponds to the second metallic interconnection layer N22 of FIG. 11. In detail, if the voltage applied to the word line WL is logic ‘1’, then the fourth PMOS transistor PG22 may be turned on to connect the complementary bit line BL′ to the second node N22. The second node N22 is connected to input terminals of the first inverter, e.g., the gates of the first NMOS transistor PD21 and the first PMOS transistor PU21, and is connected to output terminals of the second inverter, e.g., the drains of the second NMOS transistor PD22 and the second PMOS transistor PU22.

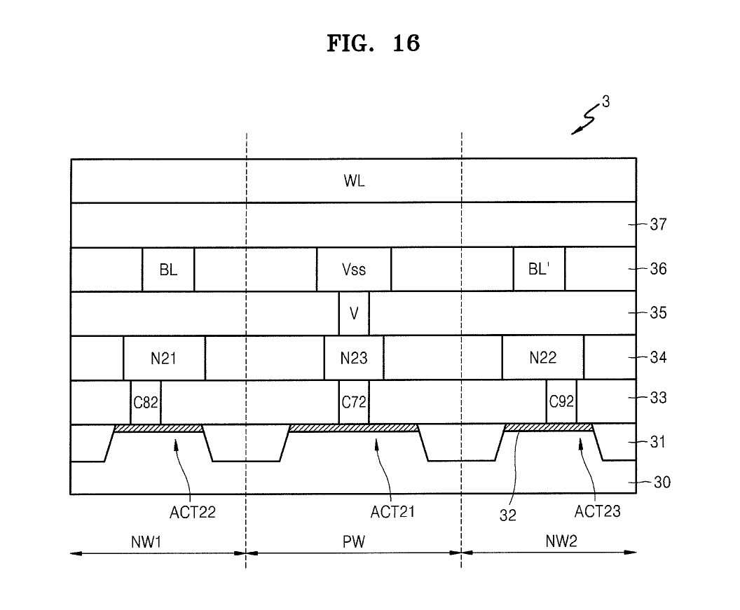

FIG. 16 is a cross-sectional view of the semiconductor memory device 3 of FIG. 11, taken along line III-III′. Referring to FIG. 16, the semiconductor memory device 3 is formed on a substrate 30 in which the P well region PW and the first and second N well regions NW1 and NW2 are defined. The substrate 30 may be substantially the same as the substrate 10 described above with reference to FIG. 6 and will thus not be described again here.

The P well region PW may be formed by implanting P type ions into the substrate 30, and the first and second N well regions NW1 and NW2 may be formed by implanting N type ions into the substrate 30. First to third active regions ACT21, ACT22, and ACT23 defined by an isolation layer 31 may be disposed in the P well region PW and the first and second N well regions NW1 and NW2, respectively. The isolation layer 31 may be a shallow trench isolation (STI) layer. A silicide layer 32 may be formed on the first to third active regions ACT21, ACT22, and ACT23.

A first insulating layer 33 is disposed on the substrate 30, and the fifth contact plug C82, the second contact plug C72, and the eighth contact plug C92 are disposed on the first insulating layer 33. The fifth contact plug C82 is connected to the second active region ACT22, the second contact plug C72 is connected to the first active region ACT21, and the eighth contact plug C82 is connected to the third active region ACT23. A second insulating layer 34 is disposed on the first insulating layer 33, and the first and second metallic interconnection layers N21 and N22 and a third metallic interconnection layer N23 are disposed on the first insulating layer 33. The third metallic interconnection layer N23 connects the ground voltage line Vss to the first active region ACT21.

A third insulating layer 35 is disposed on the second insulating layer 34, and a via plug V is disposed on the third insulating layer 35. A fourth insulating layer 36 is disposed on the third insulating layer 35, and the pair of bit lines BL and BL′ and the ground voltage line Vss are disposed on the fourth insulating layer 36. A fifth insulating layer 37 is disposed on the fourth insulating layer 36, and the word line WL is disposed on the fifth insulating layer 37. The first to fifth insulating layers 33 to 37 may be substantially the same as the first to fifth insulating layers 13 to 17 described above with reference to FIG. 6, and will not be described again here.

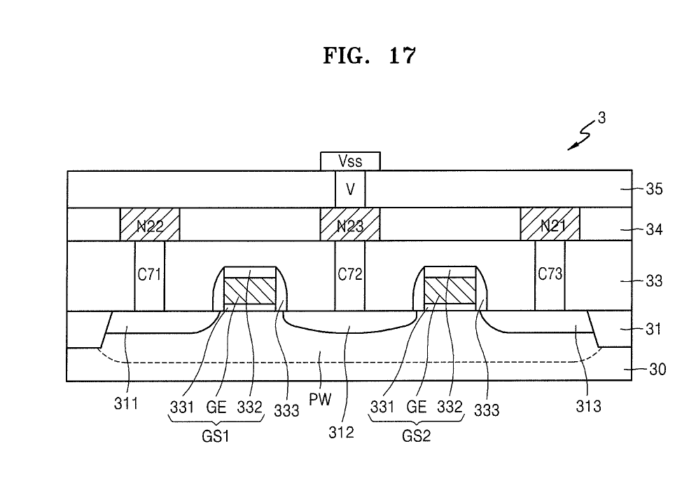

FIG. 17 is a cross-sectional view of the semiconductor memory device 3 of FIG. 11, taken along line IV-IV′. Referring to FIG. 17, the semiconductor memory device 3 is formed on the substrate 30 having the P well region PW. The P well region PW is defined by the isolation layer 31 formed on the substrate 30.

First and second gate stacks GS1 and GS2 are disposed on the P well region PW. Each of the first and second gate stacks GS1 and GS2 may include a gate insulating layer 331, a gate electrode layer GE, and a capping layer 332. Specifically, each of the first and second gate stacks GS1 and GS2 may be formed by sequentially forming the gate insulating layer 331, the gate electrode layer GE, and the capping layer 332 on the P well region PW and then patterning the resultant structure. Spacers 333 are disposed on sidewalls of the first and second gate stacks GS1 and GS2, respectively. The gate insulating layer 331, the gate electrode layer GE, and the capping layer 332 may be substantially the same as the gate insulating layer 131, the gate electrode layer GE, and the capping layer 132 described above with reference to FIG. 7 and will not be described again here.

The first insulating layer 33 is disposed on the first and second gate stacks GS1 and GS2, and the first to third contact plugs C71, C72, and C73 are disposed on the first insulating layer 33. The first to third contact plugs C71, C72, and C73 are connected to source and drain regions 311, 312, and 313, respectively. Although not shown, a silicide layer may be formed on the source and drain regions 311, 312, and 313.

The second insulating layer 34 is disposed on the first insulating layer 33, and the first to third metallic interconnection layers N21 to N23 are disposed on the second insulating layer 34. The third insulating layer 35 is disposed on the second insulating layer 34, and the via plug V is disposed on the third insulating layer 35. The ground voltage line Vss is disposed on the via plug V.

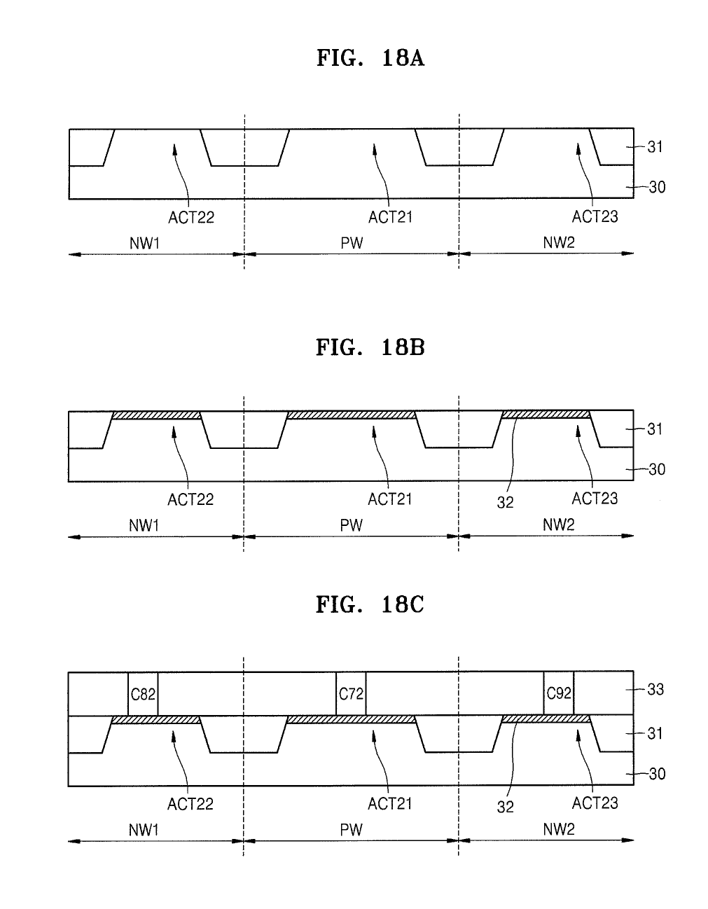

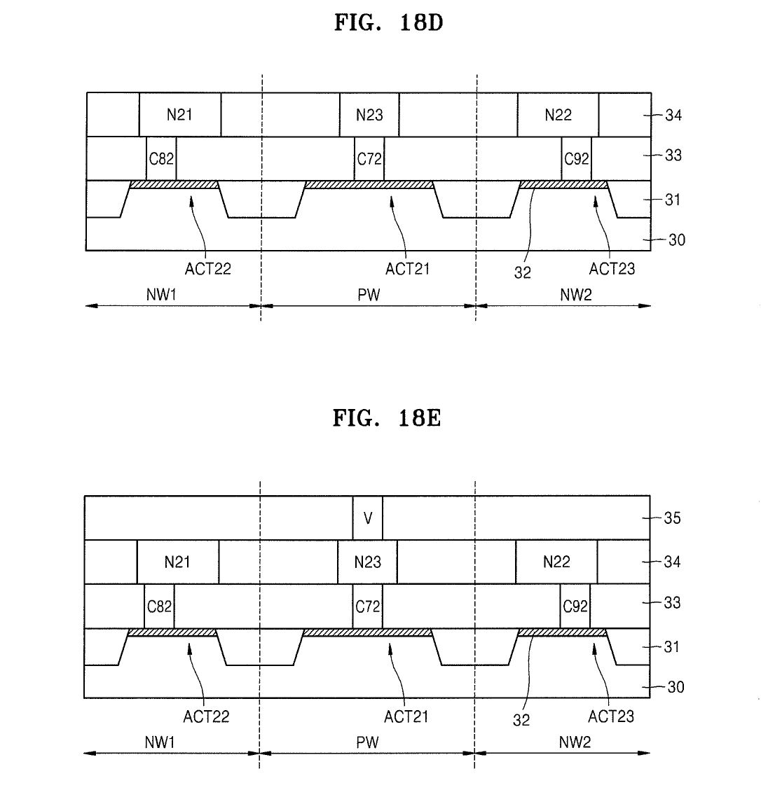

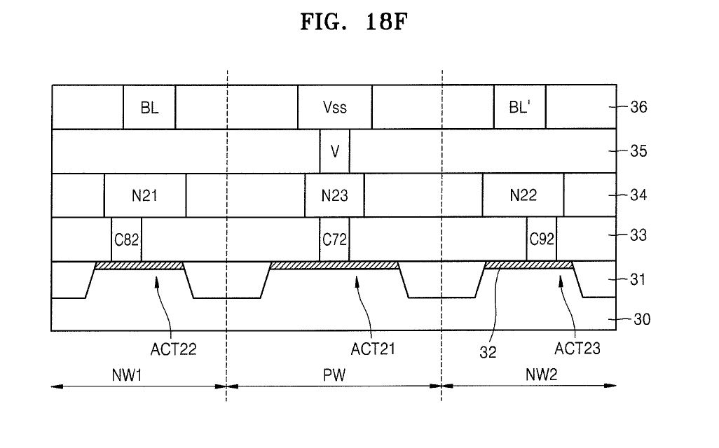

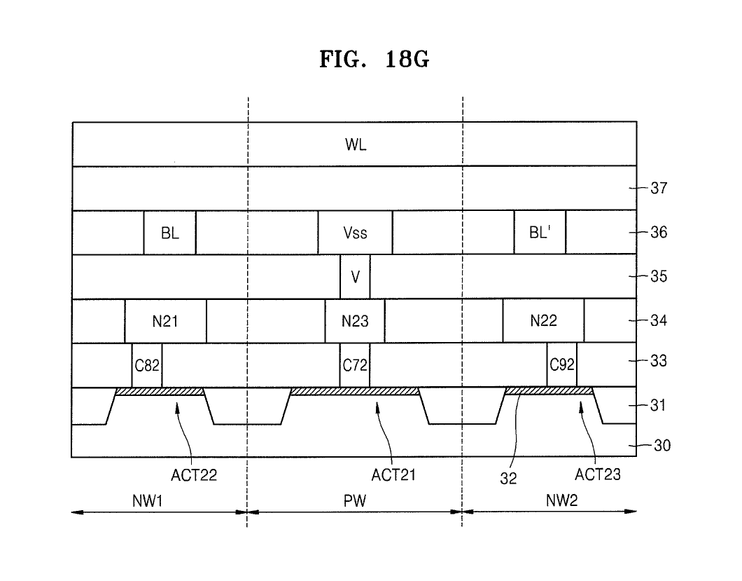

FIGS. 18A to 18G are cross-sectional views illustrating a method of manufacturing a semiconductor memory device, according to an exemplary embodiment of the inventive concept. Referring to FIG. 18A, a substrate 30 includes a P well region PW in which NMOS transistors are to be formed, and a first N well region NW1 and a second N well region NW2 in which PMOS transistors are to be fanned. A first active region ACT21 is formed in the P well region PW, a second active region ACT22 is formed in the first N well region NW1, and a third active region ACT23 is formed in the second N well region NW2. The first to third active regions ACT21, ACT22, and ACT23 may be defined by an isolation layer 31, such as an STI layer.

Referring to FIG. 18B, a silicide layer 32 is formed on the first to third active regions ACT21, ACT22, and ACT23. Specifically, the silicide layer 32 may be formed on the first to third active regions ACT21, ACT22, and ACT23 by forming a metal layer (not shown) on the substrate 30 and thermally processing the resultant substrate 30. If the silicide layer 32 is formed as described above, then contact resistance between the first to third active regions ACT21, ACT22, and ACT23 and contact plugs that are to be formed may be reduced.

Referring to FIG. 18C, a first insulating layer 33 is formed on the substrate 30. Next, a mask layer is formed on the first insulating layer 33 according to a photolithography process to expose a region where a plurality of first contact holes (not shown) are to be formed. Next, first contact holes (not shown) are formed in the first insulating layer 33 according to a dry etching process and then are filled with a metal material, thereby forming fifth, second, and eighth contact plugs C82, C72, and C92. Here, the fifth, second, and eighth contact plugs C82, C72, and C92 may be formed in a manner substantially similar to the manner in which the fifth, second and eighth contact plugs C22, C12, and C32 are formed as described above with reference to FIG. 8C.

Referring to FIG. 18D, a second insulating layer 34 is formed on the first insulating layer 33. Next, a plurality of second contact holes (not shown) may be formed in the second insulating layer 34 and then may be filled with a metal material, thereby forming a first metallic interconnection layer N21, a second metallic interconnection layer N22, and a third metallic interconnection layer N13.

Referring to FIG. 18E, a third insulating layer 35 is formed on the second insulating layer 34. Next, a third contact hole (not shown) may be formed in the third insulating layer 35 and may then be filled with a metal material, thereby forming a via plug V. The via plug V may be formed in a manner substantially similar to the manner in which the via plug V is formed as described above with reference to FIG. 8E.

Referring to FIG. 18F, a fourth insulating layer 36 is formed on the third insulating layer 35. Next, a plurality of fifth contact holes (not shown) may be formed in the fourth insulating layer 36 and may then be filled with a metal material, thereby forming a bit line BL, a ground voltage line Vss, and a complementary bit line BL′. In another exemplary embodiment of the inventive concept, the bit line BL and the complementary bit line BL′ may be formed on a layer on which the ground voltage line Vss is not formed. In another exemplary embodiment of the inventive concept, the bit line BL, the complementary bit line BL′, and the ground voltage line Vss may be formed below the first to third metallic interconnection layers N21, N22, and N23, respectively.

Referring to FIG. 18G, a fifth insulating layer 37 and a word line WL are sequentially formed on the fourth insulating layer 36. In another exemplary embodiment of the inventive concept, the word line WL may be formed below the bit line BL and the complementary bit line BL′. In another exemplary embodiment of the inventive concept, the word line WL may be formed below the first to third metallic interconnection layers N21, N22, and N23.

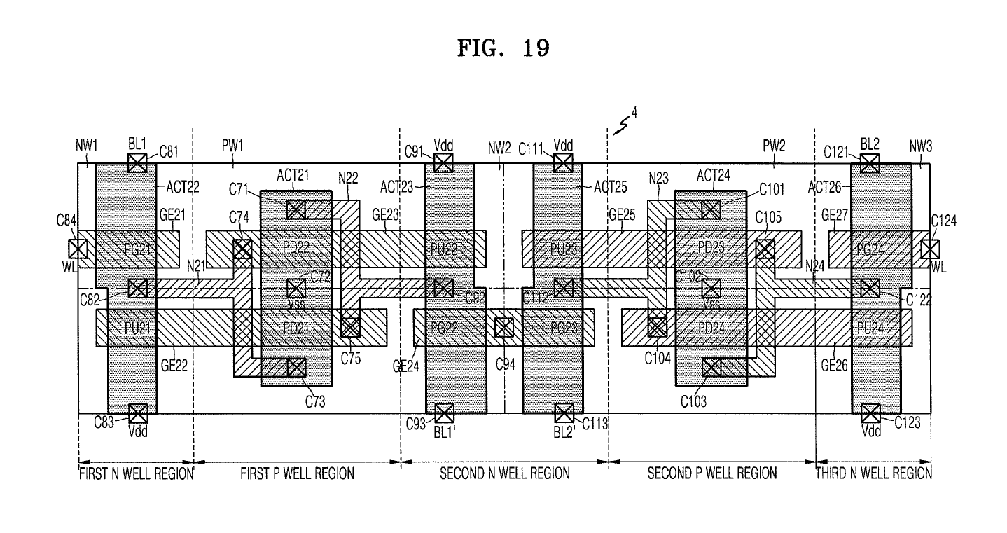

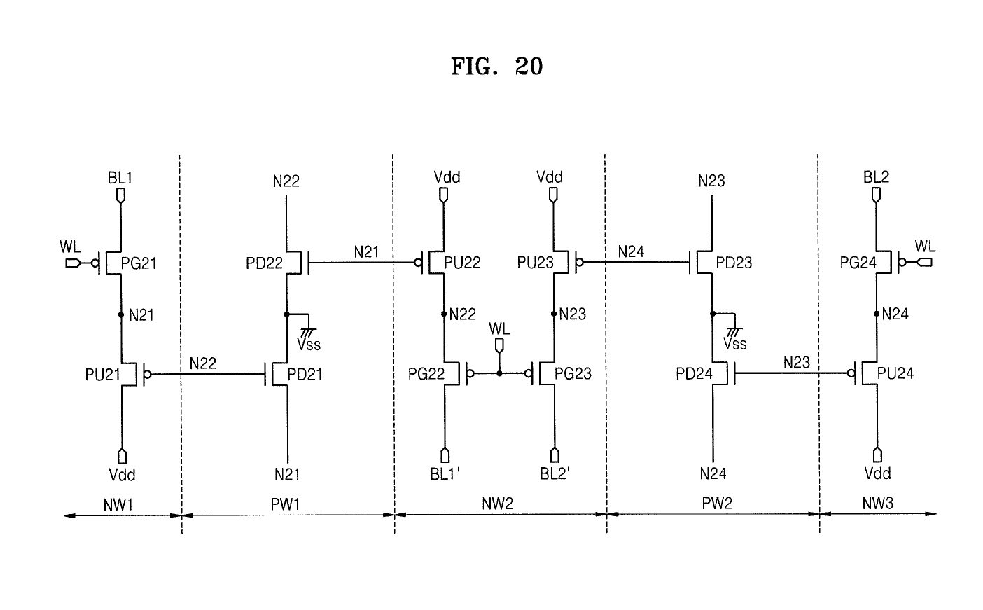

FIG. 19 is a layout diagram of a semiconductor memory device 4 according to an exemplary embodiment of the inventive concept. Referring to FIG. 19, the semiconductor memory device 4 includes two SRAM cells formed on a substrate, in which a first P well region PW1 is defined, a first N well region NW1 and a second N well region NW2 are defined having the first P well region PW1 therebetween, a second P well region PW2 is defined, and the second N well region NW2 and a third well region NW3 are defined having the second P well region PW2 therebetween.

The first and second P well region PW1 and PW2 are regions in which a P type well is formed, for example, through ion implantation. A first active region ACT21 and a fourth active region ACT24, which are defined by an isolation layer, are disposed in the first and second P well region PW1 and PW2, respectively. In the current embodiment, each of the first and fourth active regions ACT21 and ACT24 may be one bar-type active region formed to be long in the vertical direction.

In this case, an N type diffusion region may be obtained by doping N+ type impurities onto the first active region ACT21, and contact plugs C71, C72, and C73 may be formed in the first active region ACT21. In the first active region ACT21, two pull-down devices may be formed in a line. In the current embodiment, the two pull-down devices may be first and second NMOS transistors PD21 and PD22. In addition, an N type diffusion region may be obtained by doping N+ type impurities onto the fourth active region ACT24, and contact plugs C101, C102, and C103 may be formed in the fourth active region ACT24. In the fourth active region ACT24, two pull-down devices may be formed in a line. In the current embodiment, the two pull-down devices may be third and fourth NMOS transistors PD23 and PD24.

In the first N well region NW1, an N type well is formed in the substrate, for example, through ion implantation. The first N well region NW1 includes a second active region ACT22 defined by an isolation layer. In the current embodiment, the second active region ACT22 may be one active region that extends in parallel with the first and fourth active regions ACT21 and ACT24.

In this case, a P type diffusion region may be obtained by doping P+ type impurities onto the second active region ACT22, and contact plugs C81, C82, and C83 may be formed in the second active region ACT22. In the second active region ACT22, one pull-up device and one access device may be formed. In the current embodiment, the pull-up device may be a first PMOS transistor PU21, and the access devices may be a third PMOS transistor PG21.

In the second N well region NW2, an N type well is formed in the substrate, for example, through ion implantation. The second N well region NW2 includes a third active region ACT23 and a fifth active region ACT25 defined by an isolation layer. In the current embodiment, the third and fifth active regions ACT23 and ACT25 may be single active regions that extend in parallel with the first and fourth active regions ACT21 and ACT24, respectively.

In this case, a P type diffusion region may be obtained by doping P+ type impurities onto the third active region ACT23, and contact plugs C91, C92, and C93 may be formed in the third active region ACT23. In the third active region ACT23, one pull-up device and one access device may be formed. In the current embodiment, the pull-up device may be a second PMOS transistor PU22 and the access device may be a fourth PMOS transistor PG22.

In addition, a P type diffusion region may be obtained by doping P+ type impurities onto the fifth active region ACT25, and contact plugs C111, C112, and C113 may be formed in the fifth active region ACT25. In the fifth active region ACT25, one pull-up device and one access device may be formed. In the current embodiment, the pull-up device may be a fifth PMOS transistor PU23 and the access device may be a seventh PMOS transistor PG23.

In the third N well region NW3, an N type well is formed in the substrate, for example, through ion implantation. The third N well region NW3 includes a sixth active region ACT26 defined by an isolation layer. In the current embodiment, the sixth active region ACT26 may be one active region that extends in parallel with the first and fourth active regions ACT21 and ACT24.

In this case, a P type diffusion region may be obtained by doping P+ type impurities onto the sixth active region ACT26, and contact plugs C121, C122, and C123 may be formed in the sixth active region ACT26. In the sixth active region ACT26, one pull-up device and one access device may be formed. In the current embodiment, the pull-up device may be a sixth PMOS transistor PU24 and the access device may be an eighth PMOS transistor PG24.

In the current embodiment, the width of an N well region may be substantially the same as that of a P well region adjacent to the N well region. Specifically, the first P well region PW1, the second N well reign NW2, and the second P well reign PW2 may have the substantially the same width. Thus, a patterning process for forming well regions may be easily performed during the manufacture of the semiconductor memory device 4.

In addition, in the current embodiment, the first and third active regions ACT21 and ACT23 may have a symmetrical structure with respect to the fourth and fifth active regions ACT24 and ACT25, respectively. Accordingly, a photolithography process for forming active regions may be easily performed during the manufacture of the semiconductor memory device 4.

First to seventh gate electrodes GE21, GE22, GE23, GE24, GE25, GE26, and GE27 are formed on the substrate having the first to sixth active regions ACT21 to ACT26. Specifically, the first gate electrode GE21 is disposed to cross the second active region ACT22, the second gate electrode GE22 is disposed to cross the first and second active regions ACT21 and ACT22, the third gate electrode GE23 is disposed to cross the first and third active regions ACT21 and ACT23, and the fourth gate electrode GE24 is disposed to cross the third and fifth active regions ACT23 and ACT25. The fifth gate electrode GE25 is disposed to cross the fourth and fifth active regions ACT24 and ACT25, the sixth gate electrode GE26 is disposed to cross the fourth and sixth active region ACT24 and ACT26, and the seventh gate electrode GE27 is disposed to cross the sixth active region ACT26. In this case, word line contact plugs C84, C94, and C124 are formed on the first, fourth, and seventh gate electrodes GE21, GE24, and GE27, respectively, and interconnection contact plugs C75, C74, C105, and C104 are formed on the second, third, fifth, and sixth gate electrodes GE22, GE23, GE25, and GE26, respectively.

First to fourth metallic interconnection layers N21, N22, N23, and N24 are formed on the substrate on which the first to seventh gate electrodes GE21 to GE27 are formed. The first metallic interconnection layer N21 connects the contact plug C73 formed on the first active region ACT21, the contact plug C82 formed on the second active region ACT22, and the interconnection contact plug C74 formed on the third gate electrode GE23 with one another. The second metallic interconnection layer N22 connects the contact plug C71 formed on the first active region ACT21, the contact plug C92 formed on the third active region ACT23, and the interconnection contact plug C75 formed on the second gate electrode GE22 with one another. The third metallic interconnection layer N23 connects the contact plug C101 formed on the fourth active region ACT24, the contact plug C112 formed on the fifth active region ACT25, and the interconnection contact plug C104 formed on the sixth gate electrode GE26 with one another. The fourth metallic interconnection layer N24 connects the contact plug C103 formed on the fourth active region ACT24, the contact plug C122 formed on the sixth active region ACT26, and the interconnection contact plug C105 formed on the fifth gate electrode GE25 with one another.

In the semiconductor memory device 4 according to the current embodiment, the first PMOS transistor PU21, the first NMOS transistor PD21, the fourth PMOS transistor PG22, the seventh PMOS transistor PG23, the fourth NMOS transistor PD24, and the sixth PMOS transistor PU24 may be horizontally arranged in a line, and the third PMOS transistor PG21, the second NMOS transistor PD22, the second PMOS transistor PU22, the fifth PMOS transistor PU23, the third NMOS transistor PD23, and the eighth PMOS transistor PG24 may be horizontally arranged in a line.

In addition, in the semiconductor memory device 4, the first and third PMOS transistors PU21 and PG21 may be vertically arranged in a line in the first N well region NW1, the first and second NMOS transistors PD21 and PD22 may be vertically arranged in a line in the first P well region PW1, the fourth and second PMOS transistors PG22 and PU22 may be vertically arranged in a line in the second N well region NW2, the seventh and fifth PMOS transistors PG23 and PU23 may be vertically arranged in a line in the second N well region NW2, and the fourth and third NMOS transistors PD24 and PD23 may be vertically arranged in a line in the second P well reign PW2, and the sixth and eighth PMOS transistors PU24 and PG24 may be vertically arranged in a line in the third N well region NW3.

FIG. 20 is a circuit diagram of an equivalent circuit of the semiconductor memory device 4 of FIG. 19, according to an exemplary embodiment of the inventive concept. Referring to FIG. 20, the semiconductor memory device 4 includes first and third PMOS transistors PU21 and PG21 disposed in a first N well region NW1, first and second NMOS transistors PD21 and PD22 disposed in a first P well region PW1, second, fourth, fifth, and seventh PMOS transistors PU22, PG22, PU23, and PG23 disposed in a second N well region NW2, third and fourth NMOS transistors PD23 and PD24 disposed in a second P well region PW2, and sixth and eighth PMOS transistors PU24 and PG24 disposed in a third N well region NW3.

The first NMOS transistor PD21 and the first PMOS transistor PU21 form a first inverter, the second NMOS transistor PD22 and the second PMOS transistor PU22 form a second inverter, the third NMOS transistor PD23 and the fifth PMOS transistor PU23 form a third inverter, and the fourth NMOS transistor PD24 and the sixth PMOS transistor PU24 form a fourth inverter.

The third PMOS transistor PG21 may be switched on or off according to a voltage applied to a word line WL and may connect a bit line BL1 to a first node N21. The first node N21 corresponds to the first metallic interconnection layer N21 illustrated in FIG. 19. In detail, if the voltage applied to the word line WL is logic ‘0’, then the third PMOS transistor PG21 may be turned on to connect the bit line BL1 to the first node N21. The first node N21 is connected to input terminals of the second inverter, e.g., gates of the second NMOS transistor PD22 and the second PMOS transistor PU22, and is connected to output terminals of the first inverter, e.g., drains of the first NMOS transistor PD21 and the first PMOS transistor PU21.

The fourth PMOS transistor PG22 may be switched on or off according to the voltage applied to the word line WL and may connect a complementary bit line BL1′ to a second node N22. The second node N22 corresponds to the second metallic interconnection layer N22 illustrated in FIG. 19. In detail, if the voltage applied to the word line WL is logic ‘0’, then the fourth PMOS transistor PG22 may be turned on to connect the complementary bit line BL1′ to the second node N22. The second node N22 is connected to input terminals of the first inverter, e.g., gates of the first NMOS transistor PD21 and the first PMOS transistor PU21, and is connected to output terminals of the second inverter, e.g., drains of the second NMOS transistor PD22 and the second PMOS transistor PU22.

The seventh PMOS transistor PG23 may be switched on or off according to the voltage applied to the word line WL and may connect a complementary bit line BL2′ to a third node N23. The third node N23 corresponds to the third metallic interconnection layer N23 illustrated in FIG. 19. In detail, if the voltage applied to the word line WL is logic ‘0’, then the seventh PMOS transistor PG23 may be turned on to connect the complementary bit line BL2′ to the third node N23. The third node N23 is connected to input terminals of the fourth inverter, e.g., gates of the fourth NMOS transistor PD24 and the sixth PMOS transistor PU24, and is connected to output terminals of the third inverter, e.g., drains of the third NMOS transistor PD23 and the fifth PMOS transistor PU23.

The eighth PMOS transistor PG24 may be switched on or off according to the voltage applied to the word line WL and may connect a bit line BL2 to a fourth node N24. The fourth node N24 corresponds to the fourth metallic interconnection layer N24 illustrated in FIG. 19. In detail, if the voltage applied to the word line WL is logic ‘0’, then the eighth PMOS transistor PG24 may be turned on to connect the bit line BL2 to the fourth node N24. The fourth node N24 is connected to input terminals of the third inverter, e.g., gates of the third NMOS transistor PD23 and the fifth PMOS transistor PU23, and is connected to output terminals of the fourth inverter, e.g., drains of the fourth NMOS transistor PD24 and the sixth PMOS transistor PU24.

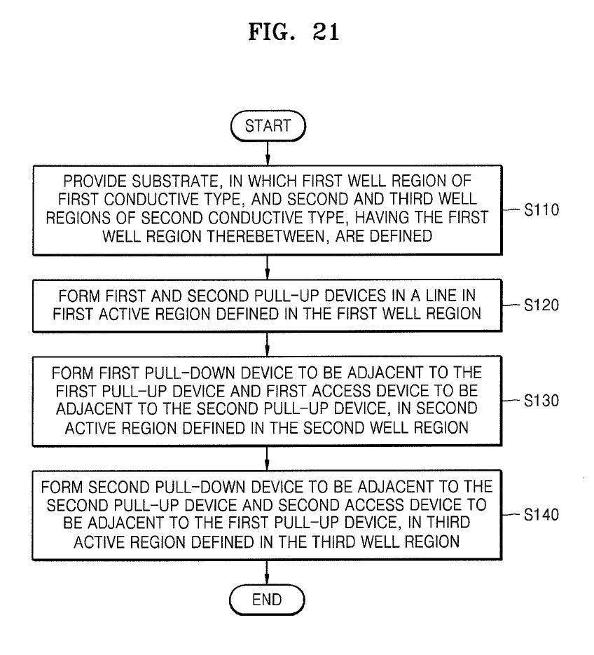

FIG. 21 is a flowchart illustrating a method of manufacturing a semiconductor memory device according to an exemplary embodiment of the inventive concept. The method of FIG. 21 is a process of manufacturing a semiconductor memory device as described above with reference to FIGS. 1 to 10. Thus, the exemplary embodiments described above with reference to FIGS. 1 to 10 may be applied to the method of FIG. 21.

Referring to FIG. 21, in operation 5110, a substrate is provided, in which a first well region of a first conductive type is defined, and second and third well regions of a second conductive type are defined having the first well region therebetween.

In operation S120, a first pull-up device and a second pull-up device are formed in a line in a first active region defined in the first well region.

In operation S130, a first pull-down device is formed to be adjacent to the first pull-up device and a first access device is formed to be adjacent to the second pull-up device, in a second active region defined in the second well region.

In operation S140, a second pull-down device is formed to be adjacent to the second pull-up device and a second access device is formed to be adjacent to the first pull-up device, in a third active region defined in the third well region.

In the current embodiment, the first and second pull-up devices may be disposed in a line and in a first direction, the first pull-up device may be disposed adjacent to the first pull-down device and the second access device in a second direction perpendicular to the first direction, and the second pull-up device may be disposed adjacent to the second pull-down device and the first access device in the second direction.

The method of FIG. 21 may further include forming a plurality of conductive patterns on the substrate to cross an upper part of at least one from among the first to third active regions. In this case, the first pull-up device and the first pull-down device may be commonly connected to one of the plurality of conductive patterns, thereby forming a first inverter, and the second pull-up device and the second pull-down device may be commonly connected another conductive pattern of the plurality of conductive patterns, thereby forming a second inverter.

The method of FIG. 21 may further include forming a first metallic interconnection layer for connecting one end of the first access device to input terminals of the second inverter and output terminals of the first inverter, and a second metallic interconnection layer for connecting one end of the second access device to input terminals of the first inverter and output terminals of the second inverter. According to an exemplary embodiment of the inventive concept, the first and second metallic interconnection layers may be formed on the same layer, but according to another exemplary embodiment of the inventive concept, the first and second metallic interconnection layers may be formed on different layers.

The forming of the first and second metallic interconnection layers may include forming a first insulating layer on the substrate, forming a plurality of first contact holes by partially etching the first insulating layer, forming a plurality of contact plugs by filling the plurality of first contact holes with a metal material, forming a second insulating layer on the first insulating layer having the plurality of contact plugs, forming a plurality of second contact holes by partially etching the second insulating layer, and forming the first and second metallic interconnection layers by filling the plurality of second contact holes with a metal material. The first and second metallic interconnection layers may be connected to at least one from among the first to third well regions via the plurality of contact plugs.

The method of FIG. 21 may further include forming a silicide layer on at least one of the first to third well regions. The plurality of contact plugs may be connected to the silicide layer.

The method of FIG. 21 may further include forming a pair of bit lines on the substrate to extend in the first direction. From among the pair of bit lines, a first bit line may be connected to the other end of the first access device and a second bit line may be connected to the other end of the second access device.

The method of FIG. 21 may further include forming a power supply voltage line on the substrate to extend in the first direction. The power supply voltage line may be connected to the first and second pull-up devices via the contact plug between the first and second pull-up devices.

The method of FIG. 21 may further include forming a word line on the substrate to extend in the second direction.

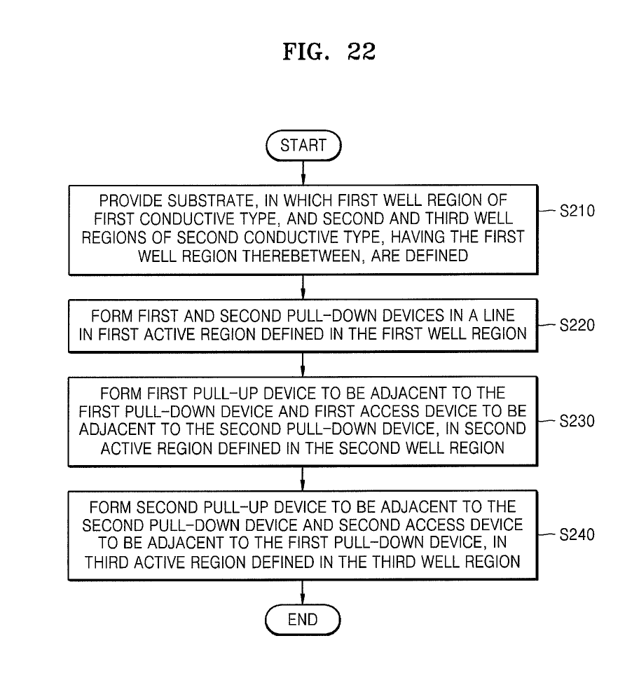

FIG. 22 is a flowchart illustrating a method of manufacturing a semiconductor memory device, according to an exemplary embodiment of the inventive concept. The method of FIG. 22 is a process of manufacturing a semiconductor memory device as described above with reference to FIGS. 11 to 20. Thus, the exemplary embodiments described above with reference to FIGS. 11 to 20 may be applied to the method of FIG. 22.

Referring to FIG. 22, in operation S210, a substrate is provided, in which a first well region of a first conductive type is defined, and a second well region and a third well region of a second conductive type are defined having the first well region therebetween.

In operation S220, a first pull-down device and a second pull-down device are formed in a line in a first active region defined in the first well region.

In operation S230, a first pull-up device is formed to be adjacent to the first pull-down device and a first access device is formed to be adjacent to the second pull-down device, in a second active region defined in the second well region.

In operation S240, a second pull-up device is formed to be adjacent to the second pull-down device and a second access device is formed to be adjacent to the first pull-down device, in a third active region defined in the third well region.

In the current embodiment, the first and second pull-down devices may be disposed in a line and in a first direction, the first pull-down device may be disposed adjacent to the first pull-up device and the second access device in a second direction perpendicular to the first direction, and the second pull-down device may be disposed adjacent to the second pull-up device and the first access device in the second direction.

The method of FIG. 22 may further include forming a plurality of conductive patterns on the substrate to cross an upper part of at least one from among the first to third active regions. The first pull-down device and the first pull-up device may be commonly connected to one of the plurality of conductive patterns, thereby forming a first inverter, and the second pull-down device and the second pull-up device may be commonly connected another conductive pattern of the plurality of conductive patterns, thereby forming a second inverter.

The method of FIG. 22 may further include forming a first metallic interconnection layer for connecting one end of the first access device to input terminals of the second inverter and output terminals of the first inverter, and a second metallic interconnection layer for connecting one end of the second access device to input terminals of the first inverter and output terminals of the second inverter. According to an exemplary embodiment of the inventive concept, the first and second metallic interconnection layers may be formed on the same layer, but according to another exemplary embodiment of the inventive concept, the first and second metallic interconnection layers may be formed on different layers.

The forming of the first and second metallic interconnection layers may include forming a first insulating layer on the substrate, forming a plurality of first contact holes by partially etching the first insulating layer, forming a plurality of contact plugs by filling the plurality of first contact holes with a metal material, forming a second insulating layer on the first insulating layer having the plurality of contact plugs, forming a plurality of second contact holes by partially etching the second insulating layer, and forming the first and second metallic interconnection layers by filling the plurality of second contact holes with a metal material. The first and second metallic interconnection layers may be connected to at least one from among the first to third well regions via the plurality of contact plugs.

The method of FIG. 22 may further include forming a silicide layer on at least one of the first to third well regions. The plurality of contact plugs may be connected to the silicide layer.

The method of FIG. 22 may further include forming a pair of bit lines on the substrate to extend in the first direction. From among the pair of bit lines, a first bit line may be connected to the other end of the first access device and a second bit line may be connected to the other end of the second access device.

The method of FIG. 22 may further include forming a ground voltage line on the substrate to extend in the first direction. The ground voltage line may be connected to the first and second pull-down devices via the contact plug between the first and second pull-down devices.

The method of FIG. 22 may further include forming a word line on the substrate to extend in the second direction.

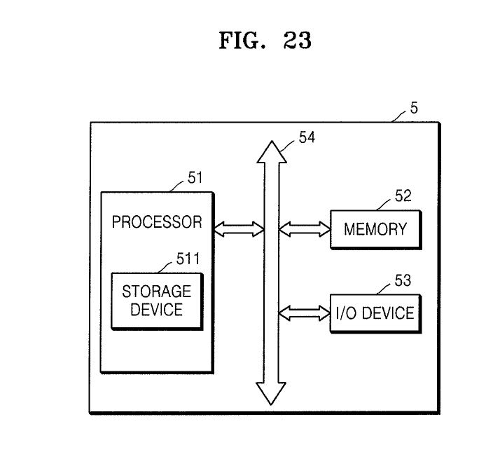

FIG. 23 is a schematic block diagram of an electronic system 5 according to an exemplary embodiment of the inventive concept. Referring to FIG. 23, the electronic system 5 may include a processor 51, a memory unit 52, and an input/output (I/O) device 53. The processor 51, the memory unit 52, and the I/O device 53 may establish data communication with one another via a bus 54. The processor 51 may run a program and control the electronic system 5. The I/O device 53 may be used to input data to or output data from the electronic system 5. The electronic system 5 may be connected to an external device, e.g., a personal computer (PC) or a network, via the I/O device 53 to exchange data with the external device. The memory unit 52 may store code and data for operating the processor 51. The processor 51 may include a storage device 511, such as cache memory, a register, or a latch. The storage device 511 may include a semiconductor memory device as described above with reference to FIGS. 1 to 20.

A semiconductor memory device according to one of various exemplary embodiments of the inventive concept may be embodied as a semiconductor module that includes a plurality of semiconductor chips. A semiconductor memory device according to one of various exemplary embodiments of the inventive concept may be applied to various devices, e.g., an embedded memory logic unit that includes memory devices, such as an SRAM, and a complementary metal oxide semiconductor (CMOS) image sensor, or may also be applied to a cell array region, a core region, a peripheral circuit region, a logic region, or an input/output region of such a device.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims.

1. A semiconductor memory device, comprising:
a substrate including first, second and third well regions, wherein the first well region is disposed between the second and third well regions, the first well region includes a first type conductor and the second and third well regions each include a second type conductor;
first and second pull-up devices disposed in a line in the first well region and sharing a power supply voltage terminal;
a first pull-down device disposed in the second well region, wherein the first pull-down device is adjacent to the first pull-up device;
a second pull-down device disposed in the third well region, wherein the second pull-down device is adjacent to the second pull-up device;
a first access device disposed in the second well region, wherein the first access device is adjacent to the second pull-up device; and
a second access device disposed in the third well region, wherein the second access device is adjacent to the first pull-up device.

2. The semiconductor memory device of claim 1, wherein the first and second pull-up devices are disposed in one active region, wherein the active region is included in the first well region.

3. The semiconductor memory device of claim 1, wherein the first pull-up device and the first pull-down device form a first inverter, and
the second pull-up device and the second pull-down device form a second inverter.

4. The semiconductor memory device of claim 3, wherein the first access device is connected to input terminals of the second inverter and output terminals of the first inverter, and
the second access device is connected to input terminals of the first inverter and output terminals of the second inverter.

5. The semiconductor memory device of claim 3, wherein the first access device includes a first access transistor that is controlled according to a voltage applied to a word line and connects a first bit line among a pair of bit lines to input terminals of the second inverter and output terminals of the first inverter.

6. The semiconductor memory device of claim 5, wherein the second access device includes a second access transistor that is controlled according to the voltage applied to the word line and connects a second bit line among the pair of bit lines to input terminals of the first inverter and output terminals of the second inverter.

7. The semiconductor memory device of claim 1, wherein the first access device and the first pull-down device are disposed in a line in one active region, wherein the active region is included in the second well region.

8. The semiconductor memory device of claim 1, wherein the second access device and the second pull-down device are disposed in a line in one active region, wherein the active region is included in the third well region.

9. The semiconductor memory device of claim 1, wherein the first type conductor is an N type conductor, and
the second type conductor is a P type conductor.

10. The semiconductor memory device of claim 9, wherein the first pull-up device includes a P-channel transistor having a source connected to the power supply voltage terminal, and
the first pull-down device includes an N-channel transistor having a drain connected to a drain of the P-channel transistor, a gate connected to a gate of the P-channel transistor, and a source connected to a ground voltage terminal.

11. The semiconductor memory device of claim 9, wherein the second pull-up device includes a P-channel transistor having a source connected to the power supply voltage terminal, and
the second pull-down device includes an N-channel transistor having a drain connected to a drain of the P-channel transistor, a gate connected to a gate of the P-channel transistor, and a source connected to a ground voltage terminal.

12. The semiconductor memory device of claim 9, wherein the first access device includes an N-channel transistor having a gate connected to a word line, and
the second access device includes an N-channel transistor having a gate connected to the word line.

13. The semiconductor memory device of claim 1, wherein the semiconductor memory device is included in an electronic system, the electronic system including a memory unit, a processor and an input/output device that communicate with each other via a bus, wherein the processor includes a storage device that includes the semiconductor memory device.

14. A semiconductor memory device, comprising:
a substrate including first, second and third well regions, wherein the first well region is disposed between the second and third well regions, the first well region includes a first type conductor and the second and third well regions each include a second type conductor;
a first active region that is included in the first well region, wherein first and second pull-up devices are disposed in a line in the first active region;
a second active region that is included in the second well region, wherein a first access device and a first pull-down device are disposed in the second active region, the first access device is disposed adjacent to the second pull-up device and the first pull-down device is disposed adjacent to the first pull-up device; and
a third active region that is included in the third well region, wherein a second access device and a second pull-down device are disposed in the third active region, the second access device is disposed adjacent to the first pull-up device and the second pull-down device is disposed adjacent to the second pull-up device.

15. The semiconductor memory device of claim 14, wherein the first and second pull-up devices are disposed in a line in a first direction,
the first pull-up device is disposed adjacent to the first pull-down device and the second access device in a second direction perpendicular to the first direction, and
the second pull-up device is disposed adjacent to the second pull-down device and the first access device in the second direction.

16. The semiconductor memory device of claim 14, further comprising:
a first gate electrode disposed on the substrate to cross lower parts of the first and second active regions; and
a second gate electrode disposed on the substrate to cross upper parts of the first and third active regions, wherein the first pull-up device and the first pull-down device are commonly connected to the first gate electrode to form a first inverter, and
the second pull-up device and the second pull-down device are commonly connected to the second gate electrode to form a second inverter.

17. The semiconductor memory device of claim 16, further comprising:
a first metallic interconnection layer configured to connect the first access device to input terminals of the second inverter and output terminals of the first inverter; and
a second metallic interconnection layer configured to connect the second access device to input terminals of the first inverter and output terminals of the second inverter.

18. The semiconductor memory device of claim 17, wherein the first and second metallic interconnection layers are disposed on the same layer.

19. The semiconductor memory device of claim 17, wherein the first and second metallic interconnection layers are disposed on different layers.

20. The semiconductor memory device of claim 16, further comprising:
a third gate electrode disposed on the substrate to cross an upper part of the second active region; and
a fourth gate electrode disposed on the substrate to cross a lower part of the third active region.

21. The semiconductor memory device of claim 20, further comprising a word line disposed on the substrate to extend in a direction parallel with the third and fourth gate electrodes to be connected to the third and fourth gate electrodes.

22. The semiconductor memory device of claim 14, further comprising a pair of bit lines disposed on the substrate to extend in a direction parallel with the first to third active regions,
wherein a first bit line from among the pair of bit lines is connected to the first access device, and
a second bit line from among the pair of bit lines is connected to the second access device.

23. The semiconductor memory device of claim 14, further comprising a power supply voltage line disposed on the substrate in a direction parallel with the first to third active regions,
wherein the power supply voltage line is connected to the first and second pull-up devices via a contact plug disposed between the first and second pull-up devices.

24. The semiconductor memory device of claim 14, wherein the first type conductor is an N type conductor, and
the second type conductor is a P type conductor.

25-30. (canceled)

31. A semiconductor memory device, comprising:
a substrate including first, second and third well regions, wherein the first well region is disposed between the second and third well regions, the first well region includes a first type conductor and the second and third regions each include a second type conductor;
first and second pull-down devices disposed in a line in the first well region and sharing a ground voltage terminal;
a first pull-up device disposed in the second well region, wherein the first pull-up device is adjacent to the first pull-down device;
a second pull-up device disposed in the third well region, wherein the second pull-up device is adjacent to the second pull-down device;
a first access device disposed in the second well region, wherein the first access device is adjacent to the second pull-down device; and
a second access device disposed in the third well region, wherein the second access device is adjacent to the first pull-down device.

32. The semiconductor memory device of claim 31, wherein the first and second pull-down devices are disposed in one active region, wherein the active region is included in the first well region.

33. The semiconductor memory device of claim 31, wherein the first pull-down device and the first pull-up device form a first inverter, and
the second pull-down device and the second pull-up device form a second inverter.

34. The semiconductor memory device of claim 33, wherein the first access device is connected to input terminals of the second inverter and output terminals of the first inverter, and
the second access device is connected to input terminals of the first inverter and output terminals of the second inverter.

35. The semiconductor memory device of claim 33, wherein the first access device includes a first access transistor that is controlled according to a voltage applied to a word line and connects a first bit line among a pair of bit lines to input terminals of the second inverter and output terminals of the first inverter.

36. The semiconductor memory device of claim 35, wherein the second access device includes a second access transistor that is controlled according to the voltage applied to the word line and connects a second bit line among the pair of bit lines to input terminals of the first inverter and output terminals of the second inverter.

37. The semiconductor memory device of claim 31, wherein the first access device and the first pull-up device are disposed in a line in one active region, wherein the active region is included in the second well region.

38. The semiconductor memory device of claim 31, wherein the second access device and the second pull-up device are disposed in a line in one active region, wherein the active region is included in the third well region.

39. The semiconductor memory device of claim 31, wherein the first type conductor is a P type conductor, and
the second type conductor is an N type conductor.

40. The semiconductor memory device of claim 39, wherein the first pull-down device includes an N-channel transistor having a source connected to the ground voltage terminal, and
the first pull-up device includes a P-channel transistor having a drain connected to a drain of the N-channel transistor, a gate connected to a gate of the N-channel transistor, and a source connected to a power supply voltage terminal.

41. The semiconductor memory device of claim 39, wherein the second pull-down device includes an N-channel transistor having a source connected to the ground voltage terminal, and
the second pull-up device includes a P-channel transistor having a drain connected to a drain of the N-channel transistor, a gate connected to a gate of the N-channel transistor, and a source connected to a power supply voltage terminal.

42. The semiconductor memory device of claim 39, wherein the first access device comprises a P-channel transistor having a gate connected to a word line, and
the second access device comprises a P-channel transistor having a gate connected to the word line.

43. The semiconductor memory device of claim 31, wherein the semiconductor memory device is included in an electronic system, the electronic system including a memory unit, a processor and an input/output device that communicate with each other via a bus, wherein the processor includes a storage device that includes the semiconductor memory device.

44. A semiconductor memory device, comprising:
a substrate including first, second and third well regions, wherein the first well region is disposed between the second and third well regions, the first well region includes a first type conductor and the second and third well regions each include a second type conductor;
a first active region that is included in the first well region, wherein first and second pull-down devices are disposed in a line in the first active region;
a second active region that is included in the second well region, wherein a first access device and a first pull-up device are included in the second active region, the first access device is disposed adjacent to the second pull-down device and the first pull-up device is disposed adjacent to the first pull-down device; and
a third active region that is included in the third well region, wherein a second access device and a second pull-up device are included in the third active region, the second access device is disposed adjacent to the first pull-down device and the second pull-up device is disposed adjacent to the second pull-down device.

45. The semiconductor memory device of claim 44, wherein the first and second pull-down devices are disposed in a line in a first direction,
the first pull-down device is disposed adjacent to the first pull-up device and the second access device in a second direction perpendicular to the first direction, and
the second pull-down device is disposed adjacent to the second pull-up device and the first access device in the second direction.

46. The semiconductor memory device of claim 44, further comprising:
a first gate electrode disposed on the substrate to cross lower parts of the first and second active regions; and
a second gate electrode disposed on the substrate to cross upper parts of the first and third active regions, wherein the first pull-down device and the first pull-up device are commonly connected to the first gate electrode to form a first inverter, and
the second pull-down device and the second pull-up device are commonly connected to the second gate electrode to form a second inverter.

47. The semiconductor memory device of claim 46, further comprising:
a first metallic interconnection layer configured to connect the first access device to input terminals of the second inverter and output terminals of the first inverter; and
a second metallic interconnection layer configured to connect the second access device to input terminals of the first inverter and output terminals of the second inverter.

48. The semiconductor memory device of claim 47, wherein the first and second metallic interconnection layers are disposed on the same layer.

49. The semiconductor memory device of claim 47, wherein the first and second metallic interconnection layers are disposed on different layers.

50. The semiconductor memory device of claim 46, further comprising:
a third gate electrode disposed on the substrate to cross an upper part of the second active region; and
a fourth gate electrode disposed on the substrate to cross a lower part of the third active region.

51. The semiconductor memory device of claim 50, further comprising a word line disposed on the substrate to extend in a direction parallel with the third and fourth gate electrodes to be connected to the third and fourth gate electrodes.

52. The semiconductor memory device of claim 44, further comprising a pair of bit lines disposed on the substrate to extend in a direction parallel with the first to third active regions,
wherein a first bit line from among the pair of bit lines is connected to the first access device, and
a second bit line from among the pair of bit lines is connected to the second access device.

53. The semiconductor memory device of claim 44, further comprising a ground voltage line disposed on the substrate in a direction parallel with the first to third active regions,
wherein the ground voltage line is connected to the first and second pull-down devices via a contact plug disposed between the first and second pull-down devices.

54. The semiconductor memory device of claim 44, wherein the first type conductor is a P type conductor, and
the second type conductor is an N type conductor.

55-58. (canceled)

59. A semiconductor memory device, comprising:
a substrate including first, second and third well regions, wherein the first well region is disposed between the second and third well regions, the first well region includes a first type conductor, and the second and third well regions each include a second type conductor, and
wherein the first well region includes a first stacked structure, the first stacked structure including a first contact plug, a first metallic insulating layer, a via plug and a power supply or ground voltage line sequentially stacked on a first single active layer;
the second well region includes a second stacked structure, the second stacked structure including a second contact plug and a second metallic insulating layer sequentially stacked on a second single active layer; and
the third well region includes a third stacked structure, the third stacked structure including a third contact plug and a third metallic insulating layer sequentially stacked on a third single active layer.
